(19) United States
(12) Patent Application Publication
(10) Pub. No.: US 2026/0314253 A1
(43) Pub. Date: Oct. 8, 2026

(54) FILM, PEROVSKITE LIGHT EMITTING DEVICE COMPRISING THE SAME AND METHOD OF MANUFACTURING THE PEROVSKITE LIGHT EMITTING DEVICE

(71) Applicant: SEOUL NATIONAL UNIVERSITY R&DB FOUNDATION, Seoul (KR)

(72) Inventors: Tae-Woo LEE, Seoul (KR); Seon-A KIM, Cheongju-si (KR)

(21) Appl. No.: 19/450,075

(22) Filed: Jan. 15, 2026

(30) Foreign Application Priority Data
Jan. 15, 2025 (KR) 10-2025-0006314
Jan. 15, 2026 (KR) 10-2026-0008056

(51) Int. Cl. H10K 85/50; H10K 50/15; H10K 50/16; H10K 50/17; H10K 71/15; H10K 85/10; H10K 85/40; H10K 85/60; H10K 102/00

(52) U.S. Cl. CPC H10K 85/50; H10K 71/15; H10K 85/1135; H10K 85/146; H10K 85/40; H10K 85/654; H10K 85/6572; H10K 50/15; H10K 50/16; H10K 50/17; H10K 50/171; H10K 2102/351

(57) ABSTRACT

The disclosure relates to a film, a perovskite light-emitting device, and a method of manufacturing the perovskite light-emitting device, wherein the film includes perovskite nanocrystals and a crosslinking compound represented by Formula 1 or 2 below, and the perovskite light-emitting device includes a first electrode, a light-emitting layer positioned on the first electrode and including the film, and a second electrode disposed on the light-emitting layer.

### CROSS-REFERENCE TO RELATED APPLICATION

This application is based on and claims priority under 35 U.S.C. § 119 to Korean Patent Application Nos. 10-2025-0006314, filed on Jan. 15, 2025, and 10-2026-0008056, filed on Jan. 15, 2026 in the Ministry of Intellectual Property, Republic of Korea, the disclosures of which are incorporated by reference herein in their entirety.

### BACKGROUND

### 1. Field

The disclosure relates to a perovskite film crosslinked by a crosslinking compound including a diazirine functional group, a perovskite light-emitting device including the same, and a method of manufacturing the perovskite light-emitting device.

### 2. Description of the Related Art

Perovskite light-emitting devices are attracting attention as next-generation display devices and high-efficiency light sources due to advantages such as excellent color purity, high luminescence efficiency, and low-temperature solution processability. Bandgap tuning of organic-inorganic hybrid materials having a perovskite structure may be easy, and light-emitting devices with various emission wavelengths may be implemented by using single-emissive layer or multi-emissive layer structures. Due to these advantages, perovskite-based light-emitting devices are being actively researched as next-generation technologies capable of replacing organic light-emitting diodes (OLEDs) and quantum dot light-emitting diodes (QLEDs).

Nonetheless, there are several technical limitations in manufacturing perovskite emissive layers and implementing devices.

First, due to the characteristics of solution-based processes, it is not easy to form a perovskite emissive layer having uniform film morphology, and local thickness variations or non-uniform crystal growth may lead to a problem in that luminescence efficiency is degraded. In addition, it has been reported that, since perovskite materials are sensitive to moisture, oxygen, heat, and electrical stress, during device operation, their crystal structure becomes unstable or their emission centers become inactive, which makes it difficult to ensure long-term reliability.

Meanwhile, in order to implement high-resolution displays, there is a need for a technique for finely patterning a perovskite emissive layer in subpixel units. However, in solution process-based methods according to the related art, there may be a problem in that, during a patterning process, damage occurs due to material dissolution and diffusion, or pattern boundaries become blurred. Although drop casting, inkjet printing, or photolithography-based approaches have been proposed, it is known that sufficient performance is difficult to achieve in terms of process compatibility, pattern clarity, and material stability.

In addition, even when high efficiency is achieved, perovskite light-emitting devices have limitations in that initial performance cannot be maintained for a long period of time due to increases in driving voltage, increases in non-radiative recombination, and interfacial deterioration, and their lifetime is shorter than that of commercial light-emitting devices of the related art. In particular, interfacial instability, increases in defect states, and reactivity with metal electrodes have been identified as the main causes of device deterioration.

Accordingly, there is still an industrial demand for the development of a crosslinker that facilitates patterning without impairing the optical and electrical properties of perovskite emissive layers, and for a perovskite light-emitting device having improved material stability, device efficiency, and lifetime through use of such a crosslinker.

### SUMMARY

Provided are a perovskite film having improved optical properties and stability of perovskite nanocrystals in preparing a film including perovskite nanocrystals and a crosslinking compound, a light-emitting device having improved device efficiency and lifetime by applying the perovskite film to an emissive layer, and a method of manufacturing the light-emitting device.

Additional aspects will be set forth in part in the description which follows and, in part, will be apparent from the description, or may be learned by practice of the presented embodiments of the disclosure.

According to an aspect of the disclosure, a film includes perovskite nanocrystals and a crosslinking compound represented by Formula 1 or 2 below:

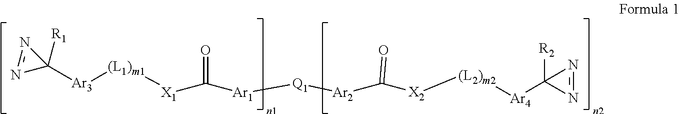

wherein, in Formula 1,
L₁ and L₂ are each independently selected from a single bond and a C₁-C₃₀ alkylene group, each unsubstituted or substituted with at least one R₁₀,
m1 and m2 are each independently 0, 1, 2, 3, 4, 5, or 6,
Ar₁ to Ar₂ are each independently selected from a single bond, a C₅-C₆₀ carbocyclic group, and a C₁-C₆₀ heterocyclic group, each unsubstituted or substituted with at least one R₁₀,
n1 and n2 are each independently 0, 1, 2, 3, 4, 5, 6, 7, 8, 9, or 10,
the sum of n1 and n2 is greater than or equal to 2,
Q₁ is selected from a single bond, O, S, Si, C, C(R₃), C(R₃)(R₄), N, N(R₃)(R₄), P, P(R₃)(R₄)(R₅), P═O(R₃), P═O(R₃) (R₄), SO₂, SO₂(R₃), and a C₁-C₃₀ alkylene group, each unsubstituted or substituted with at least one R₁₀,
X₁ is O,
X₂ is O, S, Se, N(R₆), or C(R₆)(R₇),
R₁ to R₇ and R₁₀ are each independently selected from hydrogen, deuterium, —CF₃, —CCl₃—F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group, and

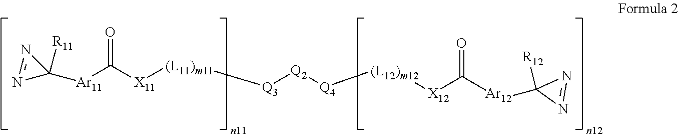

wherein, in Formula 2,
L₁₁ and L₁₂ are each independently selected from a single bond and a C₁-C₃₀ alkylene group, each unsubstituted or substituted with at least one R₁₀,
m11 and m12 are each independently 1, 2, 3, 4, 5, or 6,
Ar₁₁ and Ar₁₂ are each independently selected from a C₅-C₆₀ carbocyclic group, and a C₁-C₆₀ heterocyclic group, each unsubstituted or substituted with at least one R₁₀,
n11 and n12 are each independently 0, 1, 2, 3, 4, 5, 6, 7, 8, 9, or 10,
the sum of n11 and n12 is greater than or equal to 2,
Q₂ to Q₄ are each independently selected from a single bond, O, S, Si, C, C(R₁₃), C(R₁₃)(R₁₄), N, N(R₁₃), P, P(R₁₃)(R₁₄)(R₁₅), P═O(R₁₃), SO₂, a C₁-C₃₀ alkylene group, and any combination thereof, each unsubstituted or substituted with at least one R₁₀,
X₁₁ is O,
X₁₂ is O, S, Se, N(R₁₆), or C(R₁₆)(R₁₇),
R₁₁ to R₁₇ and R₁₀ are each independently selected from hydrogen, deuterium, —CF₃, —CCl₃, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

According to another aspect of the disclosure, a perovskite light-emitting device includes a first electrode, an emissive layer positioned on the first electrode and including the above-described film, and a second electrode disposed on the emissive layer.

According to another aspect of the disclosure, a method of manufacturing a perovskite light-emitting device includes providing a first electrode, forming, on the first electrode, an emissive layer including the above-described film, and providing a second electrode on the emissive layer, wherein the forming of the emissive layer includes obtaining a first solution in which a crosslinking compound represented by Formula 1 or 2 is dissolved in a nonpolar solvent, adding perovskite nanocrystals to the first solution and stirring to obtain a second solution, and applying the second solution onto the first electrode and patterning the applied second solution.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view illustrating a structure of a perovskite light-emitting device according to an embodiment;

FIG. 2 is a schematic view illustrating a structure of a perovskite light-emitting device according to an embodiment;

FIGS. 3A, 3B, 3C, and 3D are images showing results of patterning perovskite films having various thicknesses, according to an embodiment;

FIG. 4 shows photoluminescence quantum yield (PLQY) measurement data of perovskite solutions of Comparative Example 1 and Examples 1 to 3;

FIGS. 5A and 5B show photoluminescence (PL) spectra and PLQY data of films of Examples 4 to 6 and Comparative Example 3;

FIG. 6 shows graphs showing PL lifetime curves of films of Example 4 and Comparative Example 3;

FIG. 7 shows results of photostability tests of the films of Example 4 and Comparative Example 3;

FIGS. 8A and 8B show results of thermal stability tests of the films of Example 4 and Comparative Example 3;

FIG. 9 shows scanning electron microscope (SEM) images showing surface morphology of the film of Example 4 before and after crosslinking;

FIG. 10 shows results of water contact angle measurement of the films of Examples 4 to 6 and Comparative Example 3;

FIG. 11 is a graph showing quantum efficiency of light-emitting devices of Example 7 and Comparative Example 4;

FIG. 12 is a graph showing current density and luminance of the light-emitting devices of Example 7 and Comparative Example 4; and

FIG. 13 is a graph showing results of evaluating lifetimes of the light-emitting devices of Example 7 and Comparative Example 4.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

Since the disclosure can apply various transformations and have various embodiments, specific embodiments will be illustrated in the drawings and described in detail in the detailed description. Effects and features of the disclosure, and methods for achieving them will become clear with reference to the embodiments described below in detail together with the drawings. However, the disclosure is not limited to the embodiments disclosed below and may be implemented in various forms.

Hereinafter, embodiments of the disclosure will be described in detail with reference to the attached drawings. When describing with reference to the drawings, identical or corresponding components are given the same drawing reference numerals and redundant descriptions thereof are omitted.

In the following embodiments, the terms first, second, and the like do not have limited meaning but are used for the purpose of distinguishing one component from another component.

In the following embodiments, the expressions used in the singular such as “a,” “an,” and “the” are intended to include the plural forms as well, unless the context clearly indicates otherwise.

In the following embodiments, it will be understood that the terms such as “including,” “comprising,” and “having” specify the presence of stated features or components, but do not preclude the presence or addition of one or more other features or components.

In the following examples, it will be understood that when a component, such as a layer, a film, a region, or a plate, is referred to as being “on” another component, the component may be directly on the other component or intervening components may be present thereon. In addition, in the drawings, components may be exaggerated or reduced in size for convenience of description. For example, the size and thickness of each component shown in the drawing are arbitrarily shown for convenience of explanation, and thus the disclosure is not necessarily limited to what is shown.

### [Film]

A film according to an aspect includes perovskite nanocrystals and a crosslinking compound represented by Formula 1 or 2 below:

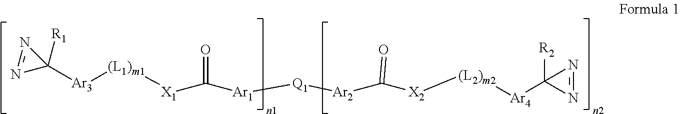

wherein, in Formula 1,
L₁ and L₂ are each independently selected from a single bond and a C₁-C₃₀ alkylene group, each unsubstituted or substituted with at least one R₁₀,
m1 and m2 are each independently 0, 1, 2, 3, 4, 5, or 6,
Ar₁ to Ar₄ are each independently selected from a single bond, a C₅-C₆₀ carbocyclic group, and a C₁-C₆₀ heterocyclic group, each unsubstituted or substituted with at least one R₁₀,
n1 and n2 are each independently 0, 1, 2, 3, 4, 5, 6, 7, 8, 9, or 10, the sum of n1 and n2 is greater than or equal to 2,
Q₁ is selected from a single bond, O, S, Si, C, C(R₃), C(R₃)(R₄), N, N(R₃)(R₄), P, P(R₃)(R₄)(R₅), P═O(R₃), P═O(R₃)(R₄), SO₂, SO₂(R₃), and a C₁-C₃₀ alkylene group, each unsubstituted or substituted with at least one R₁₀,
X₁ is O,
X₂ is O, S, Se, N(R₆), or C(R₆)(R₇),
R₁ to R₇ and R₁₀ are each independently selected from hydrogen, deuterium, —CF₃, —CCl₃—F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group, and

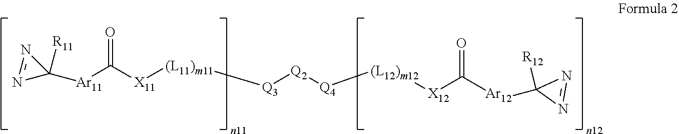

wherein, in Formula 2,
L₁₁ and L₁₂ are each independently selected from a single bond, and a C₁-C₃₀ alkylene group, each unsubstituted or substituted with at least one R₁₀,
m11 and m12 are each independently 1, 2, 3, 4, 5, or 6,
Ar₁₁ and Ar₁₂ are each independently selected from a C₅-C₆₀ carbocyclic group, and a C₁-C₆₀ heterocyclic group, each unsubstituted or substituted with at least one R₁₀,
n11 and n12 are each independently 0, 1, 2, 3, 4, 5, 6, 7, 8, 9, or 10,
the sum of n11 and n12 is greater than or equal to 2,
Q₂ to Q₄ are each independently selected from a single bond, O, S, Si, C, C(R₁₃), C(R₁₃)(R₁₄), N, N(R₁₃), P, P(R₁₃)(R₁₄)(R₁₅), P═O(R₁₃), SO₂, a C₁-C₃₀ alkylene group, and any combination thereof, each unsubstituted or substituted with at least one R₁₀,
X₁₁ is O,
X₁₁ and X₁₂ are each O, S, Se, N(R₁₆), or C(R₁₆)(R₁₇),
R₁₁ to R₁₇ and R₁₀ are each independently selected from hydrogen, deuterium, —CF₃, —CCl₃, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

It is known that perovskite nanocrystals may be inherently sensitive to external environments such as moisture, oxygen, and heat, and thus deformation and collapse of crystals may easily occur. When a film including such perovskite nanocrystals is formed, there still exists a problem in that deterioration of the perovskite nanocrystals frequently occurs during a film formation process. In order to solve the problem, attempts have been made to coat perovskite with a resin or use a specific crosslinker, but methods attempted in the past have limitations in suppressing deterioration of the perovskite nanocrystals.

Meanwhile, the inventors of the disclosure have surprisingly discovered that when perovskite nanocrystals are formed into a film by using the crosslinking compound represented by Formula 1 or 2, a uniform film may be prepared without degradation of luminescence efficiency of the perovskite nanocrystals, thereby completing the disclosure based on this finding.

### (Crosslinking Compound Represented by Formula 1)

According to an embodiment, L₁ and L₂ may each independently be selected from a methylene group, an ethylene group, a propylene group, and a butylene group, each unsubstituted or substituted with at least one R₁₀.

According to an embodiment, L₁ and L₂ may each independently be a methylene group unsubstituted or substituted with at least one R₁₀.

According to an embodiment, m1 may be 1, and m2 may be 1.

According to an embodiment, m1 may be 1.

According to an embodiment, m2 may be 1.

According to an embodiment, Ar₁ to Ar₄ may each independently be selected from a single bond, a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an aza-fluorene group, an aza-carbazole group, an aza-dibenzofuran group, an aza-dibenzothiophene group, an aza-dibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzoimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodisiline group, a dibenzodihydrosiline group, a dibenzodioxin group, a dibenzooxathine group, a dibenzooxazine group, a dibenzopyran group, a dibenzodithine group, a dibenzothiazine group, a dibenzothiopyran group, a dibenzocyclohexadiene group, a dibenzodihydropyridine group, and a dibenzodihydropyrazine group, each unsubstituted or substituted with at least one R₁₀.

According to an embodiment, Ar₁ to Ar₄ may each independently be selected from a single bond, a benzene group, a naphthalene group, a phenanthrene group, a pyrene group, and an anthracene group, each unsubstituted or substituted with at least one R₁₀.

According to an embodiment, Ar₁ to Ar₄ may each independently be selected from a single bond, and a benzene group, each unsubstituted or substituted with at least one R₁₀.

According to an embodiment, when Q₁ is an unsubstituted C₂-C₃₀ alkylene group, Ar₁ and Ar₂ may each be a single bond.

According to an embodiment, X₂ may be O, S, N(R₇), or Se.

According to another embodiment, X₂ may be O or S.

According to another embodiment, X₂ may be O.

According to another embodiment, X₂ may be S.

According to an embodiment, Q₁ may be C, and the sum of n1 and n2 may be 4.

According to an embodiment, n1 may be 0, and n2 may be 4; or n1 may be 1, and n2 may be 3; n1 may be 2, and n2 may be 2, n1 may be 3, and n2 may be 1; or n1 may be 4, and n2 may be 0.

According to another embodiment, Q₁ may be an unsubstituted C₂-C₃₀ alkylene group, and the sum of n1 and n2 may be 2.

According to an embodiment, n1 may be 1, and n2 may be 1.

According to an embodiment, R₁ to R₇ and R₁₀ may each independently be selected from: hydrogen, deuterium, —CF₃, —CCl₃, —F, —Cl, —Br, —I, a hydroxyl group, a cyano group, a C₁-C₂₀ alkyl group, a C₁-C₂₀ alkoxy group; a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, benzoimidazolyl group, a benzofuranyl group, a benzothienyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, and —Si(Q₁₁)(Q₁₂)(Q₁₃).

Q₁₁ to Q₁₃ may each independently be selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

According to another embodiment, R₁ to R₇ and R₁₀ may each independently be selected from: hydrogen, deuterium, —CF₃, —CCl₃, or a C₁-C₂₀ alkyl group; a cyclopentenyl group, a cyclohexenyl group, a cycloheptenyl group, a phenyl group, a biphenyl group, a terphenyl group, a naphthyl group, a fluorenyl group, a phenanthrenyl group, anthracenyl group, a fluoranthenyl group, a triphenylenyl group, a pyrenyl group, a chrysenyl group, a pyridinyl group, and —Si(Q₁₁)(Q₁₂)(Q₁₃).

Q₁₁ to Q₁₃ may each independently be selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

According to an embodiment, R₁ and R₂ may each independently be selected from hydrogen, deuterium, —CF₃, —F, —Cl, —Br, —I, a hydroxyl group, a cyano group, and a C₁-C₃₀ alkyl group.

According to another embodiment, R₁ and R₂ may each independently be —CF₃.

According to an embodiment, the crosslinking compound represented by Formula 1 may be represented by Formula 3-1 or 3-2 below:

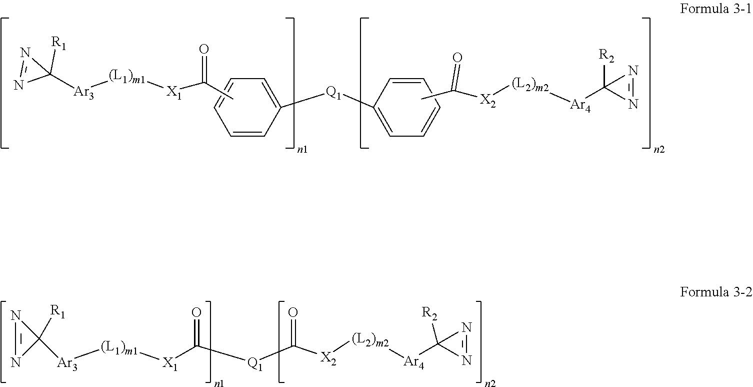

wherein, in Formulas 3-1 and 3-2, L₁, L₂, m1, m2, Ar₁, Ar₄, n1, n2, Q₁, X₁, X₂, R₁, and R₂ may be as defined herein.

According to an embodiment, the crosslinking compound represented by Formula 1 may be represented by Formula 5-1 or 5-2 below:

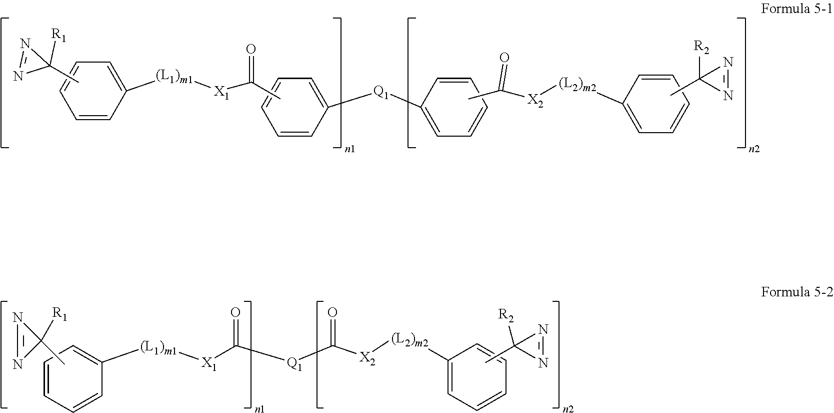

wherein, in Formulas 5-1 and 5-2, L₁, L₂, m1, m2, n1, n2, Q₁, X₁, X₂, R₁, and R₂ may be as defined herein.

According to an embodiment, the crosslinking compound represented by Formula 1 may be represented by Formula 7-1 or 7-2:

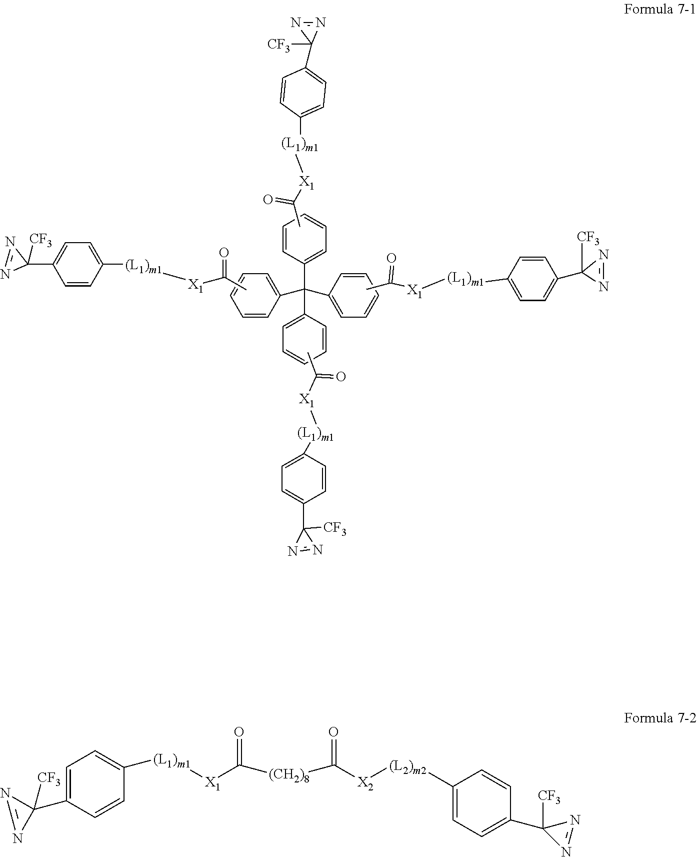

wherein, in Formulas 7-1 and 7-2, L₁, m1, and X₁ may be as defined herein.

According to an embodiment, the crosslinking compound may be Crosslinking Compound 1, Crosslinking Compound 2, or Crosslinking Compound 7 below:

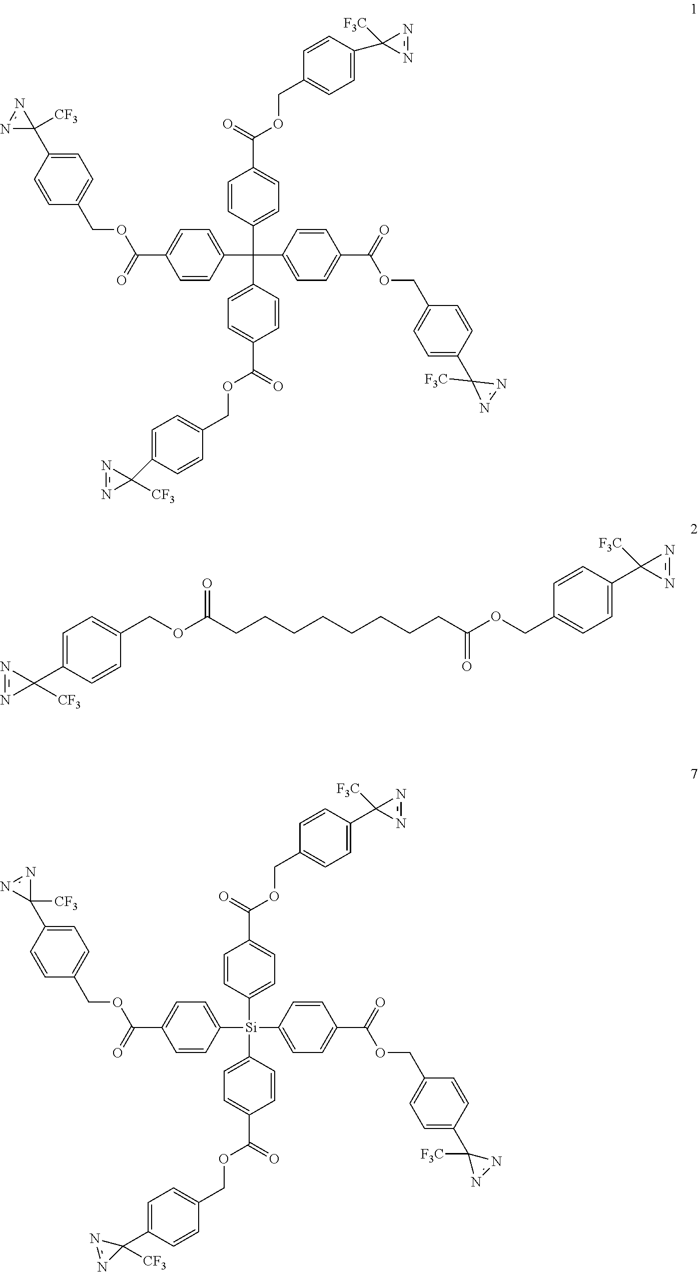 [SMILES: O=C(OCc1ccc(C2(C(F)(F)F)N=N2)cc1)c1ccc(C(c2ccc(C(=O)OCc3ccc(C4(C(F)(F)F)N=N4)cc3)cc2)(c2ccc(C(=O)OCc3ccc(C4(C(F)(F)F)N=N4)cc3)cc2)c2ccc(C(=O)OCc3ccc(C4(C(F)(F)F)N=N4)cc3)cc2)cc1 ; O=C(CCCCCCCCC(=O)OCc1ccc(C2(C(F)(F)F)N=N2)cc1)OCc1ccc(C2(C(F)(F)F)N=N2)cc1 ; O=C(OCc1ccc(C2(C(F)(F)F)N=N2)cc1)c1ccc([Si](c2ccc(C(=O)OCc3ccc(C4(C(F)(F)F)N=N4)cc3)cc2)(c2ccc(C(=O)OCc3ccc(C4(C(F)(F)F)N=N4)cc3)cc2)c2ccc(C(=O)OCc3ccc(C4(C(F)(F)F)N=N4)cc3)cc2)cc1]

### (Crosslinking Compound Represented by Formula 2)

According to an embodiment, L₁₁ and L₁₂ may each independently be selected from a single bond, a methylene group, an ethylene group, a propylene group, and a butylene group, each unsubstituted or substituted with at least one R₁₀.

According to another embodiment, L₁₁ and L₁₂ may each independently be selected from a single bond and a methylene group, each unsubstituted or substituted with at least one R₁₀.

According to an embodiment, m11 may be 1, and m12 may be 1.

According to another embodiment, m11 may be 1.

According to another embodiment, m12 may be 1.

According to an embodiment, Ar₁₁ and Ar₁₂ may each independently be selected from a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an aza-fluorene group, an aza-carbazole group, an aza-dibenzofuran group, an aza-dibenzothiophene group, an aza-dibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzoimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodisiline group, a dibenzodihydrosiline group, a dibenzodioxin group, a dibenzooxathine group, a dibenzooxazine group, a dibenzopyran group, a dibenzodithine group, a dibenzothiazine group, a dibenzothiopyran group, a dibenzocyclohexadiene group, a dibenzodihydropyridine group, and a dibenzodihydropyrazine group, each unsubstituted or substituted with at least one R₁₀.

According to another embodiment, Ar₁₁ and Ar₁₂ may each independently be selected from a benzene group, a naphthalene group, a phenanthrene group, and an anthracene group, each unsubstituted or substituted with at least one R₁₀.

According to another embodiment, Ar₁₁ and Ar₁₂ may each independently be a benzene group, unsubstituted or substituted with at least one R₁₀.

According to an embodiment, X₁₂ may be O, S, or Se.

According to another embodiment, X₁₂ may be O or S.

According to another embodiment, X₁₂ may be O.

According to another embodiment, X₁₂ may be S.

According to an embodiment, Q₂ may be C, and Q₃ and Q₄ may each independently be a single bond.

According to an embodiment, Q₂ may be O, and Q₃ and Q₄ may each independently be a combination of C(R₁₃)(R₁₄) and C.

According to another embodiment, Q₂ may be O, and Q₃ and Q₄ may each independently be C(R₁₃)(R₁₄)—C. For example, when Q₃ and Q₄ are each independently C(R₁₃)(R₁₄)—C, C(R₁₃)(R₁₄) may be bonded to Q₂ and C may be bonded to L₁₁; C(R₁₃)(R₁₄) may be bonded to Q₂ and C may be bonded to L₁₂; or both may be satisfied simultaneously.

According to an embodiment, Q₂ may be —CH₂—CH₂—, and Q₃ and Q₄ may each independently be Si.

According to another embodiment, Q₂ may be —CH₂—CH₂—, Q₃ and Q₄ may each be Si, L₁₁ and L₁₂ may each be a single bond, Q₃ and X₁₁ may be directly bonded to each other, and Q₄ and X₁₂ may be directly bonded to each other.

According to an embodiment, R₁₁ to R₁₂ and R₁₀ may each independently be selected from: hydrogen, deuterium, —CF₃, —CCl₃, —F, —Cl, —Br, —I, a hydroxyl group, a cyano group, a C₁-C₂₀ alkyl group, a C₁-C₂₀ alkoxy group; a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, benzoimidazolyl group, a benzofuranyl group, a benzothienyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, and —Si(Q₁₁)(Q₁₂)(Q₁₃).

Q₁₁ to Q₁₃ may each independently be selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

According to another embodiment, Ru to R₁₂ and R₁₀ may each independently be selected from: hydrogen, deuterium, —CF₃, —CCl₃, or a C₁-C₂₀ alkyl group; a cyclopentenyl group, a cyclohexenyl group, a cycloheptenyl group, a phenyl group, a biphenyl group, a terphenyl group, a naphthyl group, a fluorenyl group, a phenanthrenyl group, anthracenyl group, a fluoranthenyl group, a triphenylenyl group, a pyrenyl group, a chrysenyl group, a pyridinyl group, and —Si(Q₁₁)(Q₁₂)(Q₁₃).

Q₁₁ to Q₁₃ may each independently be selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

According to an embodiment, R₁₁ and R₁₂ may each independently be selected from hydrogen, deuterium, —CF₃, —F, —Cl, —Br, —I, a hydroxyl group, a cyano group, and a C₁-C₃₀ alkyl group.

According to another embodiment, R₁₁ and R₁₂ may each independently be —CF₃.

According to an embodiment, the crosslinking compound represented by Formula 2 may be represented by Formula 4-1 below:

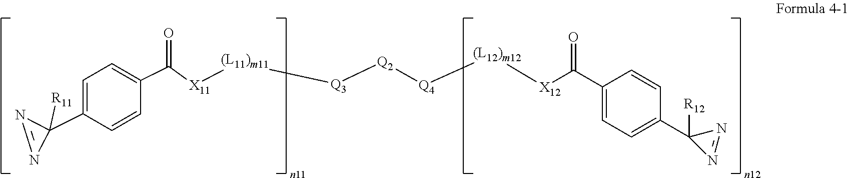

wherein, in Formula 4-1, L₁₁, L₁₂, m11, m12, n11, n12, Q₂ to Q₄, X₁₁, X₁₂, R₁₁, and R₁₂ may be as defined herein.

According to an embodiment, the crosslinking compound represented by Formula 2 may be represented by Formula 6-1 or 6-2 below:

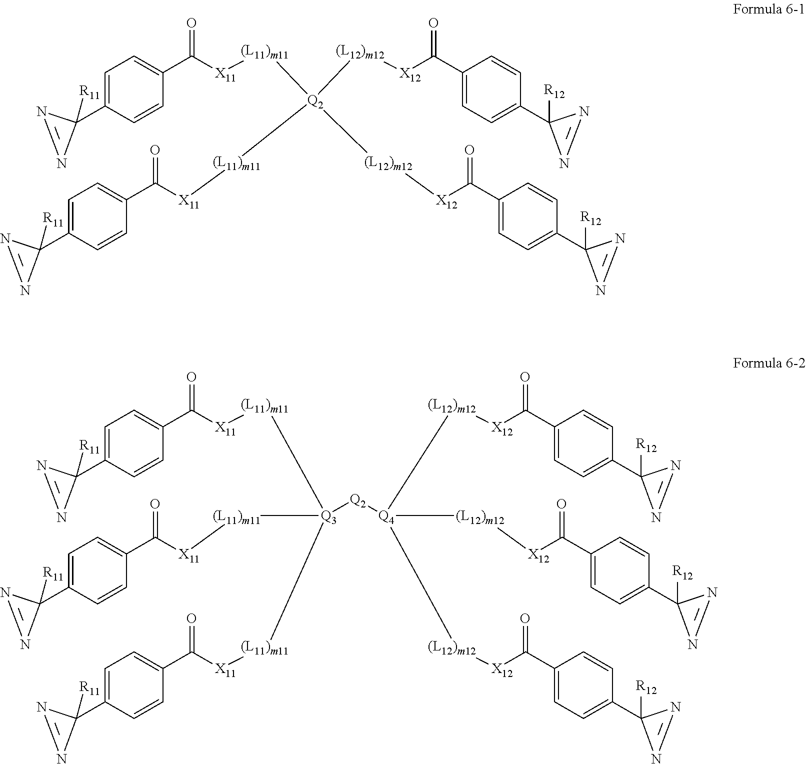

wherein, in Formulas 6-1 and 6-2, L₁₁, L₁₂, m11, m12, Q₂ to Q₄, X₁₁, X₁₂, R₁₁, and R₁₂ may be as defined herein.

According to an embodiment, in Formula 6-1, Q₂ may be C or a C₁-C₃₀ alkylene group unsubstituted or substituted with at least one R₁₀.

According to an embodiment, in Formula 6-2, Q₃ and Q₄ may each independently be C, Si, a C₁-C₃₀ alkylene group unsubstituted or substituted with at least one R₁₀, or a combination of C(R₃)(R₄) and C.

According to an embodiment, the crosslinking compound may be represented by Formula 8-1, 8-2, or 8-3 below:

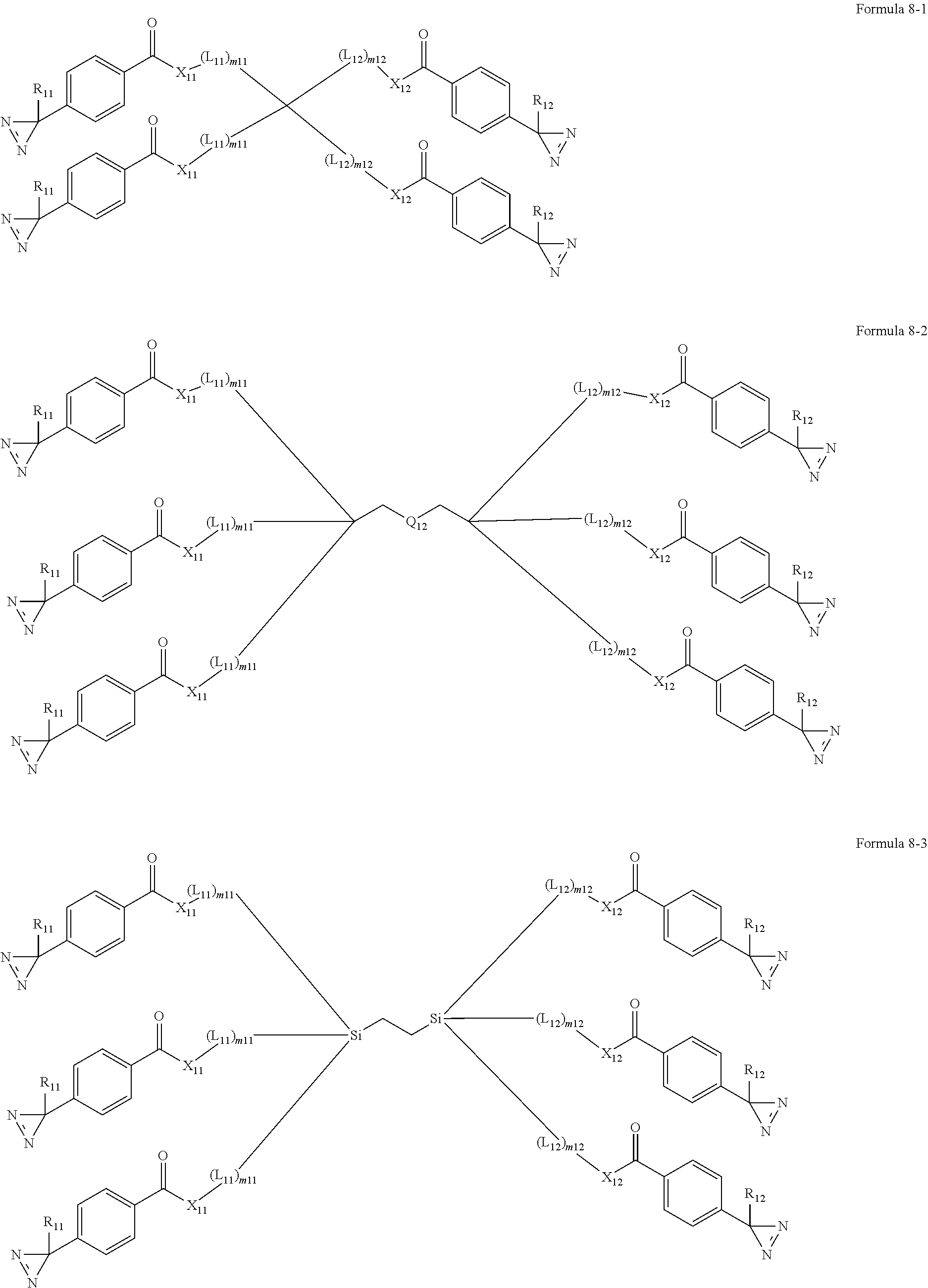

wherein, in Formulas 8-1 to 8-3, L₁₁, m11, X₁₁, and Q₂ may be as defined herein.

According to an embodiment, Q₂ may be O, S, C(R₃)(R₄), or a C₁-C₃₀ alkylene group unsubstituted or substituted with at least one R₁₀.

According to an embodiment, the crosslinking compound represented by Formula 2 may be one of Crosslinking Compounds 3 to 6 below:

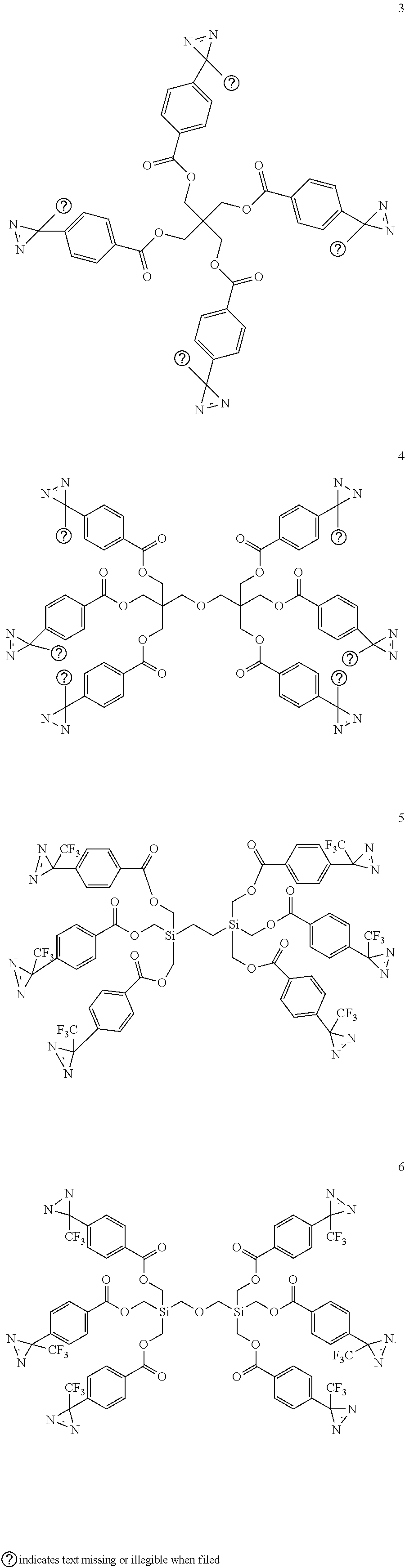

Two or more diazirine functional groups included in the crosslinking compound may increase the stability of perovskite nanocrystals by crosslinking adjacent perovskite nanocrystals and constantly maintaining gaps between nanocrystals and arranging the nanocrystals.

In addition, as the number of the diazirine functional groups included in the crosslinking compound increases, a degree of stabilization of perovskite nanocrystals increases.

Since the crosslinking compound further includes a trihaloalkyl group in addition to the diazirine functional group, an electron density at the terminal of the crosslinking compound is increased, and as a result, a surface stabilization effect of perovskite nanocrystals is improved.

The crosslinking compound may include a benzoate moiety and/or a benzyl acetate moiety having a benzene ring substituted with an alkyl group in which diazirine and trihaloalkyl groups are substituted, thereby providing a high electron density distribution over a wide area and consequently enhancing a surface stabilization effect of perovskite. Surface stabilization of perovskite not only leads to an improvement in a lifetime of a light-emitting device, but also results in improved luminescence efficiency.

In addition, the terminal electron density of the crosslinking compound may vary according to a central core structure. For example, when a central core structure has an aromatic group as in Compound 1, an electron density is higher as compared to when a central core structure has an aliphatic group as in Compound 3. In the case of Compound 1, carbene carbon to which azirine and —CF₃ groups of a crosslinking compound are bonded may be present as singlet carbene, and thus may have a high electron density distribution. In the case of Compound 3, the carbene carbon may be present as triplet carbene, and thus Compound 3 may have a lower electron density distribution as compared to Compound 1.

According to an embodiment, the perovskite nanocrystals may include a crystal structure of ABX₃, A₄BX₆, AB₂X₅, A₂BX₄, A₂BX₆, A₂B⁺B³⁺X₆, A₃B₂X₉, or A′₂Aₖ₋₁BₖX₃ₖ₊₁. A and A′ may each independently be a monovalent organic cation, a monovalent inorganic cation, or a combination thereof, B may be one or more metal ions, X may be F⁻, Cl⁻, Br⁻, I⁻, SCN⁻, OCN⁻, SeCN⁻, HCO₂⁻, CH₃COO⁻, or a combination thereof, and k may be selected from an integer from 2 to 6.

According to an embodiment, A and A′ may each include an organic amidinium ion, an organic ammonium ion, Cs, Rb, or a combination thereof.

For example, the organic amidinium ion may include a formamidinium (NH₂CH═NH⁺) ion, an acetamidinium (NH₂C(CH)═NH₂⁺) ion, a guanidinium (NHC(NH)═NH⁺) ion, an organic phosphonium (RPH₃) cation, or a monovalent alkali metal cation (for example, Cs⁺).

For example, the organic ammonium ion may include a methylammonium ion, an ethylammonium ion, a tert-butylammonium ion, a diethylammonium ion, a dimethylammonium ion, an ethane-1,2-diammonium ion, an imidazolium ion, an n-propylammonium ion, an iso-propylammonium ion, a pyrrolidinium ion, CH(NH₂)₂⁺, CₓH₂ₓ₊₁(CNH₃)⁺, (CH₃NH₃)ₙ⁺, ((CₓH₂ₓ₊₁)ₙNH₃)ₙ(CH₃NH₃)ₙ⁺, R(NH₂)₂⁺ (R is a C₁-C₁₀₀ alkyl group), (CₙH₂ₙ₊₁NH₃)ₙ⁺, (CF₃NH₃)⁺, CF₃NH₃)ₙ⁺, ((CₓF₂ₓ₊₁)ₙNH₃)ₙ(CF₃NH₃)ₙ⁺, ((CₓF₂ₓ₊₁)ₙNH₃)₂⁻, or (CₙF₂ₙ₊₁NH₃)ₙ⁺ (n and x are each independently selected from an integer from 1 to 100).

According to an embodiment, B may include a transition metal, a rare earth metal, an alkali metal, an alkaline earth metal, Pb, Sn, Ge, Ga, In, Al, Sb, Bi, Po, or a combination thereof.

For example, the rare earth metal may be Ge, Sn, Pb, Eu, or Yb, the alkali metal may be Li, Na, K, Rb, Cs, or Fr, and the alkaline earth metal may be Be, Mg, Ca, Sr, Ba, or Ra.

According to an embodiment, B may be Pb, Mn, Cu, Ga, Ge, In, Al, Sb, Bi, Po, Cu, Ag, Au, Sn, Eu, Yb, Ni, Co, Fe, Cr, Pd, Cd, Ca, Sr, or a combination thereof.

According to an embodiment, the perovskite nanocrystals may include ABX₃ nanocrystals, A may be one or more monovalent organic cations, B may be one or more metal ions, and X may be F⁻, Cl⁻, Br⁻, I⁻, or a combination thereof.

According to another embodiment, the perovskite emissive layer may include an APbBr₃ crystal structure, and A may be formamidinium (FA), guanidinium (GA), or a combination thereof.

According to an embodiment, the perovskite nanocrystals may further include an organic ligand on at least a portion of a surface thereof. Since at least a portion of the surface of the perovskite nanocrystals further includes the organic ligand, the surface of the perovskite nanocrystals may be stabilized to improve the stability of the perovskite nanocrystals, and an agglomeration phenomenon between nanocrystal nanocrystals may be prevented to improve dispersibility.

According to an embodiment, the organic ligand may include a carboxylic acid organic ligand, an amine organic ligand, a phosphonic acid organic ligand, a zwitterionic ligand, a multi-dentate ligand, or a combination thereof. The organic ligand positioned on the surface of the perovskite nanocrystals improves the dispersibility of the perovskite nanocrystals during preparation of a solution for preparing an emissive layer and constitutes a crosslinking site of the crosslinking compound.

For example, the carboxylic acid organic ligand may include 4,4′-azobis(4-cyanovaleric acid), an acetic acid, a 5-aminosalicylic acid, acrylic acid, an L-aspartic acid, a 6-bromohexanoic acid, a bromoacetic acid, a dichloroacetic acid, an ethylenediaminetetraacetic acid (EDTA), an isobutyric acid, an itaconic acid, a maleic acid, a γ-maleimidobutyric acid, an L-malic acid, a 4-nitrobenzoic acid, a 1-pyrenecarboxylic acid, a butyric acid, a pentanoic acid, a hexanoic acid, a heptanoic acid, an octanoic acid, a nonanoic acid, a decanoic acid, an undecanoic acid, a dodecanoic acid, a tridecanoic acid, a tetradecanoic acid, a pentadecanoic acid, a hexadecenoic acid, a heptadecanoic acid, an octadecanoic acid, an oleic acid, or a combination thereof. For example, the carboxylic acid organic ligand may include an oleic acid.

According to an embodiment, the amine organic ligand may include butylamine, hexylamine, octylamine, nonylamine, decylamine, undecylamine, dodecylamine, tridecylamine, tetradecylamine, pentadecylamine, hexadecylamine, heptadecylamine, octadecylamine, oleylamine, N,N-diisopropylethylamine, ethylenediamine, hexamethylenetetramine, methylamine, N,N,N,N-tetramethyleneethylenediamine, triethylamine, diethanolamine, 2,2-(ethylenedioxyl)bis-(ethylamine), 2-methyl-1,5-pentanediamine, 3-methoxytriphenyl-amine, 1,4-phenylenediamine, N,N,N,N-pentamethyl diethylenetriamine, triethylenetetramine, rhodamine, diethylamine, ethylenediamine, or a combination thereof. For example, the amine organic ligand may include decylamine.

According to an embodiment, the phosphonic acid organic ligand may include an n-hexylphosphonic acid, an n-octylphosphonic acid, an n-decylphosphonic acid, an n-dodecylphosphonic acid, an n-tetradecylphosphonic acid, an n-hexadecylphosphonic acid, an n-octadecylphosphonic acid, or a combination thereof.

According to an embodiment, the zwitterionic ligand refers to a ligand in which a cation and an anion are simultaneously present within a molecular structure. For example, the zwitterionic ligand may be electrically neutral. For example, the zwitterionic ligand may include 3-(N,N-dimethyloctadecylammonio) propanesulfonate, N-hexadecylphosphocholine, N,N-dimethyldodecylammoniumbutyrate, bethanchol chloride, or a combination thereof.

According to an embodiment, the multi-dentate ligand refers to a ligand having two or more functional groups, which may be bonded to a nanocrystal surface, within a molecular structure. For example, the multi-dentate ligand may be an ethanedioic acid, a propanedioic acid, butanedioic acid, a pentanedioic acid, a hexanedioic acid, a heptanedioic acid, an octanedioic acid, a nonanedioic acid, a decanedioic acid, an undecanedioic acid, a dodecanedioic acid, a tridecanedioic acid, a hexadecanedioic acid, a heneicosadioic acid, a 2-hydroxypropane-1,2,3-tricarboxylic acid, a 1-hydroxypropane-1,2,3-tricarboxylic acid, a prop-1-ene-1,2,3-tricarboxylic acid, a propane-1,2,3-tricarboxylic acid, a 2-hydroxynonadecane-1,2,3-tricarboxylic acid, or a benzene-1,3,5-tricarboxylic acid, but is not limited to molecular structures having-COOH groups. The multi-dentate ligand may include phosphonate, phosphinate, sulfonate, sulfinate, thiolate, primary ammonium, secondary ammonium, tertiary ammonium, quaternary ammonium, imidazolium, pyridinium, an organometallic salt, thiol, amine, phosphine, phosphine oxide, a phosphonic acid, a phosphinic acid, or a combination of functional groups thereof.

According to an embodiment, a thickness of the film may be 10 μm or less, 5 μm or less, 3 μm or less, 2.5 μm or less, 2 μm or less, 1.5 μm or less, 1 μm or less, 800 nm or less, 500 nm or less, 300 nm or less, 200 nm or less, 100 nm or less, or 50 nm or less, and may be 10 nm or more, 20 nm or more, 50 nm or more, 100 nm or more, 200 nm or more, 300 nm or more, 500 nm or more, 1 μm or more, or 2 μm or more. For example, the thickness of the film may be in a range of about 10 nm to about 10 μm, about 10 nm to about 5 μm, about 10 nm to about 3 μm, about 20 nm to about 2.5 μm, about 50 nm to about 1.5 μm, or about 100 nm to about 1 μm, but an appropriate thickness range may be configured by selecting upper and lower limit values of the thickness described above, respectively.

According to an embodiment, the film may be finely patterned. Here, the fine patterning refers to a portion developed by photocrosslinking a mixture of perovskite nanocrystals and a crosslinking compound.

According to an embodiment, a pixel size of the micropattern may be in a range of about 500 nm to about 5 mm. The pixel size may refer to a width of a pattern, and the pixel size of the micropattern may be, for example, 500 nm, 1 μm, 2 μm, 5 μm, 10 μm, 20 μm, 50 μm, 100 μm, 200 μm, 500 μm, 1 mm, 2 mm, or 5 mm. In addition, for augmented reality (AR) and virtual reality (VR) applications, a size of about 500 nm to about 5 μm is preferable for high pixel integration and high resolution implementation. The pattern may have various shapes such as stripe, circular, quadrangular, triangular, and diamond patterns, but one or more embodiments are not limited thereto.

According to an embodiment, a distance between the patterns may be 1.1 to 3 times the pixel size. Here, a distance between patterns is defined as a distance from a starting point of one pixel to a starting point of a next pixel among consecutive patterns.

An excessively small distance between pixels relative to a pixel size may deteriorate process stability and an excessively large distance between pixels may lead to reduced resolution. Therefore, it is preferable that a distance between pixels be 1.5 to 2 times a pattern size. In particular, in order to satisfy both resolution and processability for AR and VR applications, it is preferable that a pitch of the pixel be selected within a range of 1.5 to 2 times a pattern size.

According to another aspect, the film of the disclosure may include perovskite nanocrystals, the above-described crosslinking compound, an organic polymer resin, a monomer, an initiator, or additives (for example, an antioxidant and nanoparticles).

The organic polymer resin may include a photosensitive polymer and may include, for example, a negative-type or positive-type photoresist. More specifically, the organic polymer resin may be at least one of an acrylic-based, epoxy-based, phenol-based, polyimide-based, novolac-based, or SU-8-based photoresist, but is not limited thereto.

The monomer may include polymethyl methacrylate (PMMA), methyl methacrylate (MMA), isobornyl acrylate (IBOA), isobornyl methacrylate (IBOMA), or dicyclopentanyl acrylate.

The initiator may act as a photoinitiator, a thermal initiator, or a photo-thermal hybrid initiator and may include a triazine-based compound, an acetophenone-based compound, a benzophenone-based compound, a thioxanthone-based compound, a benzoin-based compound, an oxime-based compound, a carbazole-based compound, a diketone-based compound, a sulfonium borate-based compound, a diazo-based compound, a biimidazole-based compound, or a combination thereof. Specifically, the photoinitiator may absorb light to generate free radicals through b-cleavage or hydrogen adsorption and may initiate a polymerization reaction between photocurable compositions. More specifically, the photoinitiator may include at least one selected from Omnirad 184, Omnirad 651, Omnirad 819, 2,4,6-trimethylbenzoyl-diphenyl phosphine oxide (TPO), isopropylthioxanthone (ITX), 2,4-diethylthioxanthone (DETX), and Michler's ketone (MK, [(CH₃)₂NC₆H₄]₂CO), or 4,4′-bis(N,N-diethylamino)benzophenone (DEABP), but one or more embodiments are not limited thereto. Meanwhile, the thermal initiator may absorb heat energy and decompose to generate free radicals and may initiate a polymerization reaction or a crosslinking reaction. As an example, the thermal initiator may include an azo-based compound, a peroxide-based compound, a peroxide ester-based compound, or a peroxyketal-based compound. More specifically, the thermal initiator may be selected from azobisisobutyronitrile (AIBN), azobis(2-methylbutyronitrile), 1,1′-azobis(cyclohexanecarbonitrile), benzoyl peroxide (BPO), lauroyl peroxide (LPO), dicumyl peroxide (DCP), tert-butyl peroxybenzoate, or a combination thereof, but one or more embodiments are not limited thereto.

The additives (nanoparticles) may be included to improve the mechanical stability, thermal stability, optical properties, or process compatibility of the film (for example, improve luminescence efficiency, light scattering, and light extraction efficiency, and adjust a refractive index), and may include, for example, inorganic nanoparticles. The inorganic nanoparticles may be selected from TiO₂, SiO₂, SnO₂, Al₂O₃, ZrO₂, HfO₂, ZnO, MgO, or a mixture thereof. In particular, considering compatibility with a color conversion layer (CCL) process, the inorganic nanoparticles may include nanoparticles that provide insulation, thermal conductivity, or interfacial stability. The inorganic nanoparticles may have an average particle size of about 20 nm to about 500 nm.

The additive (antioxidant) may be included to inhibit oxidative degradation of perovskite nanocrystals, a crosslinking compound, or an organic polymer component within a film to improve optical properties and long-term stability. The antioxidant may function to inhibit radical reactions induced by oxygen, moisture, or light irradiation or reduce irreversible deterioration reactions through the decomposition of peroxides. Examples of the antioxidants may include a phenol-based antioxidant, a phosphorus-based antioxidant, a sulfur-based antioxidant, an amine-based antioxidant, a naturally derived antioxidant, and the like, but one or more embodiments are not limited thereto. More specific examples of the antioxidants may include butylated hydroxytoluene (BHT), butylated hydroxyanisole (BHA), Irganox 1010, Irganox 1076, Irgafos 168, tris(2,4-di-tert-butylphenyl) phosphite, dilauryl thiodipropionate (DLTP), or a mixture thereof, but one or more embodiments are not limited thereto.

Preferably, in order to maximize light absorption efficiency and emission intensity at the same film thickness, the film may include only the perovskite nanocrystals and the crosslinking compound.

As described above, it has been difficult to prepare a film having a micrometer-scale thickness due to a problem in that perovskite nanocrystals are damaged during a film formation process, and thus physical properties of the perovskite nanocrystals are degraded, and there is still a demand for micrometer-thick films suitable for thick-film patterning.

In the past, resins and photoinitiators have been used for thick-film patterning of perovskite films. However, such a method has caused degradation of the physical properties of perovskite nanocrystals, an aggregation phenomenon of nanocrystals, and distortion of patterns during patterning due to high viscosity.

However, in a film according to an embodiment of the disclosure, by crosslinking perovskite nanocrystals with the above-described crosslinking compound, crystals are stabilized through crosslinking without deterioration of the physical properties of the perovskite nanocrystals. As a result, a micrometer-thick film that is suitable for thick-film patterning may be prepared. A perovskite film prepared in this way has an advantage in that a content of a resin matrix of a related art is lowered to increase a concentration and density of perovskite in a thick film, thereby maximizing absorption and emission at the same thickness.

A perovskite light-emitting device according to an aspect includes a first electrode, an emissive layer positioned on the first electrode and including the above-described crosslinking compound and perovskite nanocrystals, and a second electrode positioned on the emissive layer.

In the perovskite light-emitting device according to an aspect, the crosslinking compound may crosslink and stabilize the perovskite nanocrystals, thereby improving the efficiency and long lifetime characteristics of the light-emitting device.

For details on the crosslinking compound and the perovskite nanocrystals included in the emissive layer, reference is made to the above-described contents.

According to an embodiment, the crosslinking compound crosslinks a plurality of perovskite compounds (or nanocrystals) included in the emissive layer, thereby effectively suppressing ion migration between the perovskite nanocrystals and improving the lifetime of a device.

According to an embodiment, the emissive layer may have a thickness of about 10 nm to about 100 nm. More specifically, the thickness of the emissive layer may be 100 nm or less, 90 nm or less, 80 nm or less, 70 nm or less, 60 nm or less, 50 nm or less, 40 nm or less, 30 nm or less, 20 nm or less, or 10 nm or less, and may be 1 nm or more, 2 nm or more, 5 nm or more, 10 nm or more, 20 nm or more, 30 nm or more, 40 nm or more, 50 nm or more, or 60 nm or more. For example, the thickness of the emissive layer may be in a range of about 1 nm to about 100 nm, about 2 nm to about 90 nm, about 5 nm to about 80 nm, about 10 nm to about 70 nm, about 20 nm to about 60 nm, or about 30 nm to about 50 nm, and is not limited to such a numerical range. An appropriate thickness range may be configured by selecting upper and lower limit values of the thickness of the above-described emissive layer, respectively.

According to an embodiment, the perovskite emissive layer may have a single-layer structure or a multilayer structure. For example, when the perovskite emissive layer has a multilayer structure, respective layers may include the same or different perovskite nanocrystals.

Meanwhile, in the emissive layer of the perovskite light-emitting device according to an embodiment of the disclosure, the perovskite nanocrystals in the emissive layer may be firmly crosslinked through the crosslinking compound without degradation of physical properties, and preferably, a high electron density at the terminal of the crosslinking compound may also simultaneously stabilize a surface of the perovskite nanocrystals. Thus, aggregation of the perovskite nanocrystals may be prevented, and deterioration of the perovskite nanocrystals may also be minimized, thereby enabling formation of a uniform and precise perovskite emissive layer irrespective of thickness.

According to an embodiment, the perovskite light-emitting device may further include a hole transport region between the first electrode and the emissive layer and may further include an electron transport region between the emissive layer and the second electrode, wherein the hole transport region may include a hole injection layer, a hole transport layer, or any combination thereof, and the electron transport region may include an electron injection layer, an electron transport layer, or any combination thereof.

In the emissive layer of the perovskite light-emitting device according to an embodiment of the disclosure, the stability of the perovskite nanocrystals may be significantly improved, thereby improving the efficiency and luminance of a device.

According to an embodiment, the emissive layer may be a patterned perovskite film. A perovskite film may be patterned to be suitable for application to high-resolution or large-area light-emitting devices.

A method of manufacturing a perovskite light-emitting device according to an aspect includes providing a first electrode, forming, on the first electrode, an emissive layer including the above-described crosslinking compound and perovskite nanocrystals, and providing a second electrode on the emissive layer, wherein the forming of the emissive layer includes obtaining a first solution in which the above-described crosslinking compound represented by Formula 1 or 2 is dissolved in a nonpolar solvent, adding the perovskite nanocrystals to the first solution and stirring to obtain a second solution, and applying the second solution onto the first electrode and patterning the applied second solution.

According to an embodiment, the nonpolar solvent used in preparing the first solution may be toluene, n-hexane, 1-octadecene, octane, chlorobenzene, chloroform, or a combination thereof. For example, the nonpolar solvent used in preparing the first solution may include toluene.

According to an embodiment, the applying may include spin coating. After the spin coating, the method may further including maintaining for 2 to 25 minutes.

According to an embodiment, between the providing of the first electrode and the forming of the emissive layer, the method may further include providing a hole injection layer and a hole transport layer on the first electrode.

According to an embodiment, between the forming of the emissive layer and the providing of the second electrode, the method may further include providing an electron transport layer between the emissive layer and the second electrode.

According to an embodiment, the patterning may include positioning a photomask on a coating film, then irradiating ultraviolet (UV) light, and then performing development with a nonpolar solvent.

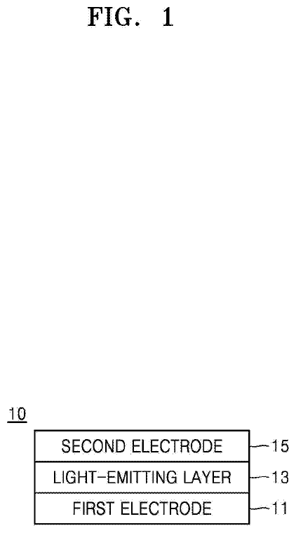

Next, a light-emitting device according to an embodiment of the disclosure will be described with reference to FIG. 1.

FIG. 1 is a schematic cross-sectional view illustrating the light-emitting device according to an embodiment of the disclosure. The light-emitting device according to an embodiment of the disclosure includes a first electrode 11, an emissive layer 13, and a second electrode 15.

Although not specifically shown in FIG. 1, a substrate for supporting the light-emitting device may be further included below the first electrode 11. The substrate may consist of a transparent or opaque material or a rigid or flexible material according to the application field and use of the light-emitting device. For example, the substrate may consist of a light-transmissive material such as glass, a ceramic material, polycarbonate (PC), polyethylene terephthalate (PET), polyethylene naphthalate (PEN), polyimide (PI), or polypropylene (PP). However, one or more embodiments are not limited thereto, and the substrate may be a metal substrate capable of reflecting light.

The first electrode 11 may be an anode that generates holes according to an externally applied voltage and injects the holes into the emissive layer or the hole transport region. The first electrode 11 may have transparency or reflection characteristics according to a bottom-emission structure or a top-emission structure in which light is emitted toward the substrate.

The first electrode 11 may consist of a material having a high work function to facilitate hole injection and have low surface resistance to provide a uniform current distribution to the emissive layer or the hole transport region. In addition, in order to suppress short-circuit occurrence, it is preferable to lower surface roughness of an interface with an adjacent layer (for example, the emissive layer or the hole transport layer).

The first electrode 11 may consist of a conductive metal oxide, a metal alloy, a conductive polymer, a carbon material, or a combination thereof. For example, the first electrode 11 may include indium tin oxide (ITO), fluorine-doped tin oxide (FTO), zinc oxide (ZnO), aluminum-doped zinc oxide (AZO), tin oxide (SnO₂), graphene, carbon nanotubes (CNTs), poly(3,4-ethylenediothiophene):polystyrenesulfonate (PEDOT:PSS), or a combination thereof.

The first electrode 11 may be formed on the substrate by using a method such as sputtering, evaporation, solution coating, printing, or chemical vapor deposition (CVD) using the above-described material. When an electrode-forming material is a conductive polymer, an electrode may be formed through a solution-based process such as spin coating, slot-die coating, or inkjet printing. In addition, if necessary, a surface of the first electrode 11 may be subjected to oxygen plasma treatment, UV-ozone treatment or heat treatment to remove contaminants and adjust a work function.

When the light-emitting device is a light-emitting diode, and a conductive polymer is used as the first electrode 11, a perovskite thin film as an emissive layer may be formed directly on the first electrode 11 without additional deposition of a hole injection layer. On the other hand, when another type of electrode other than a conductive polymer is used as the first electrode 11, a hole transport region may be formed on the first electrode 11.

Next, the above-described emissive layer 13 may be formed on the first electrode 11. For a method of manufacturing the emissive layer and a configuration of the emissive layer, reference is made to the above description.

The emissive layer 13 may be formed by applying an emissive layer-forming solution, which contains perovskite nanocrystals and a crosslinking compound, onto the first electrode 11 or the hole transport region, maintaining or drying the first electrode 11 for a predetermined period of time, and then performing spin coating using a spin coater. In this case, a maintaining or drying time may be in a range of about 2 minutes to about 25 minutes.

Next, the second electrode 15 may be formed. The second electrode 15 may be formed on the emissive layer 13 or an electron transport region (not shown).

The second electrode 15 may be a cathode that injects electrons into the emissive layer or the electron transport region when an external voltage is applied, and may consist of a material having a low work function to facilitate electron injection.

The second electrode 15 may consist of a metal such as aluminum, gold, magnesium, calcium, sodium, potassium, indium, yttrium, lithium, silver, lead, or cesium, or an alloy thereof.

According to an embodiment, the second electrode 15 may have a single-layer or multilayer structure. When the second electrode 15 has a multilayer structure, materials forming respective layers may be the same or different.

The second electrode 15 may be formed on the emissive layer or the electron transport region by using the above-described materials through a method commonly used in the art, and the disclosure is not particularly limited thereto. For example, the second electrode 15 may be formed through a dry process, a solution (wet) process, and the like. The dry process may include any general dry process used in the art, such as a thermal evaporation process, a vacuum deposition process, an atomic layer deposition (ALD) process, a CVD process, a physical vapor deposition (PVD) process, or an air jet process, and the solution process may include any general solution process used in the art, such as a spin coating process, a slot die coating process, a blade coating process, a printing coating process, a gravure coating process, or a spray coating process.

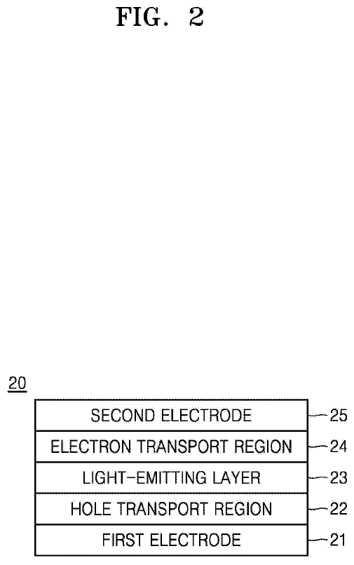

A light-emitting device according to an embodiment of the disclosure will be described with reference to FIG. 2.

FIG. 2 is a schematic cross-sectional view illustrating the light-emitting device according to an embodiment of the disclosure. The light-emitting device according to an embodiment of the disclosure includes a first electrode 21, a hole transport region 22, an emissive layer 23, an electron transport region 24, and a second electrode 25.

For details on the first electrode 21, the emissive layer 23, and the second electrode 25, reference is made to the contents of FIG. 1.

The hole transport region 22 may be provided between the first electrode 21 and the emissive layer 23 to facilitate hole injection. The hole transport region 22 may include a hole injection layer, a hole transport layer, or a combination thereof.

The hole transport region 22 may include materials commonly used as hole transport materials, and materials for the hole injection layer and/or the hole transport layer may be selected and used in consideration of highest occupied molecular orbital (HOMO) energy levels of materials so as to facilitate hole injection. Materials for the hole transport region 22 may include at least one selected from compounds including an aryl group and/or a heteroaryl group, polymers of the compounds, and derivatives of the compounds, and specifically, examples thereof may include mCP (N,N′-dicarbazolyl-3,5-benzene), PEDOT:PSS, N,N′-di(1-naphthyl)-N,N′-diphenylbenzidine (NPD), N,N′-diphenyl-N,N′-di(3-methylphenyl)-4,4′-diaminobiphenyl (TPD), poly[N,N′-bis(4-butylphenyl)-N,N′-bisphenylbenzidine] (Poly-TPD), N4,N4′-Bis[4-[bis(3-methylphenyl)amino]phenyl]-N4,N4′-diphenyl-[1,1′-biphenyl]-4,4′-diamine (DNTPD), N,N′-diphenyl-N,N′-dinaphthyl-4,4′-diaminobiphenyl, N,N,N′,N′-tetra-p-tolyl-4,4′-diaminobiphenyl, N,N,N′,N′-tetraphenyl-4,4′-diaminobiphenyl, a porphyrin compound derivative such as copper (II) 1,10,15,20-tetraphenyl-21H,23H-porphyrin, 1,1-bis[4-[N,N′-di(p-tolyl)amino]phenyl]cyclohexane (TAPC), N,N,N-tri(p-tolyl)amine, a triarylamine derivative such as 4,4′,4″-tris[N-(3-methylphenyl)-N-phenylamino]triphenylamine, a carbazole derivative such as N-phenylcarbazole or polyvinylcarbazole (PVK), a phthalocyanine derivative such as metal-free phthalocyanine or copper phthalocyanine, a starburst amine derivative, an enamine stilbene-based derivative, derivatives of an aromatic tertiary amine and a styryl amine compound, or polysilane. Such a hole transport material may also function as an electron blocking layer.

The emissive layer 23 is stacked on the hole transport region 22, and for details on the emissive layer 23, reference is made to the above description.

The electron transport region 24 may be provided between the second electrode 25 and the emissive layer 23 to facilitate electron injection. The electron transport region 24 may include an electron transport layer, an electron injection layer, or a combination thereof.

The electron transport region 24 may include materials commonly used as electron transport materials, and materials for the electron transport layer and/or the electron transport layer may be selected and used in consideration of lowest unoccupied molecular orbital (LUMO) energy levels of materials so as to facilitate electron injection.

The electron injection layer may include LiF, NaCl, CsF, Li₂O, BaO, BaF₂, or lithium quinolate (Liq).

The electron transport layer may include at least one selected from compounds containing an aryl group and/or a heteroaryl group, polymers of the compounds, and derivatives of the compounds. Specifically, the electron transport layer may include diphenylphosphine oxide-4-(triphenylsilyl)phenyl (TSPO1), 1,3,5-tris(N-phenylbenzimidazol-2-yl)benzene (TPBi), 1,3,5-tri (m-pyridin-3-ylphenyl)benzene (TmPyPB), 4,6-bis(3,5-di(pyridin-3-yl)phenyl)-2-methylpyrimidine (B3PYMPM), 2,4,6-tris[3-(diphenylphosphinyl)phenyl]-1,3,5-triazine (PO-T2T), 3′,3′″,3″″-(1,3,5-triazine-2,4,6-triyl)tris(([1,1′-biphenyl]-3-carbonitrile)) (CN-T2T), 2-[4-(9,10-di-naphthalen-2-yl-anthracen-2-yl)phenyl]-1-phenyl-1H-benzimidazole (ZADN), tris(2,4,6-trimethyl-3-(pyridin-3-yl)phenyl)borane (3TPYMB), tris(8-quinolinolato)aluminum (Alq3), a 2,5-diaryl silole derivative (PyPySPyPy), a perfluorinated compound (PF-6P), octasubstituted cyclooctatetraenes (COTs), 3-(4-biphenyl)-4-phenyl-5-tert-butylphenyl-1,2,4-triazole (TAZ), Bphen (4,7-diphenyl-1,10-phenanthroline), BCP (2,9-dimethyl-4,7-diphenyl-1,10-phenanthroline), bis(2-methyl-8-quinolinolate)-4-(phenylphenolato)aluminum (BAlq), bis(10-hydroxybenzo[h]quinolinato)beryllium (BeBq2), 1,3,5-tri(p-pyrid-3-yl-phenyl)benzene (TpPyPB), or a combination thereof.

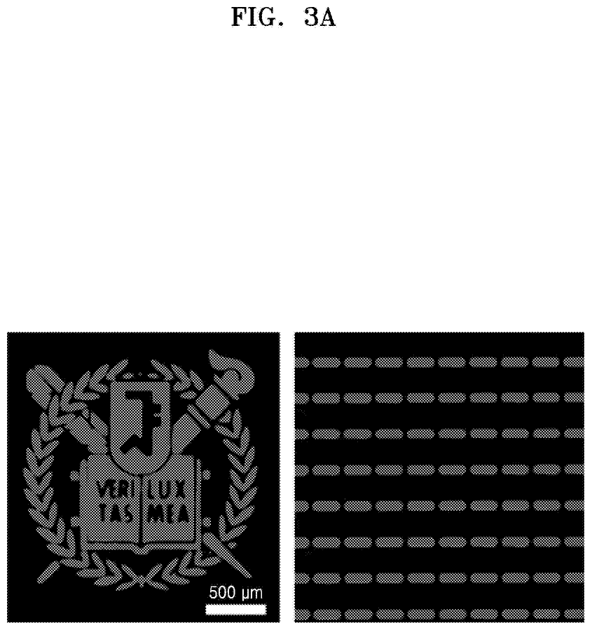

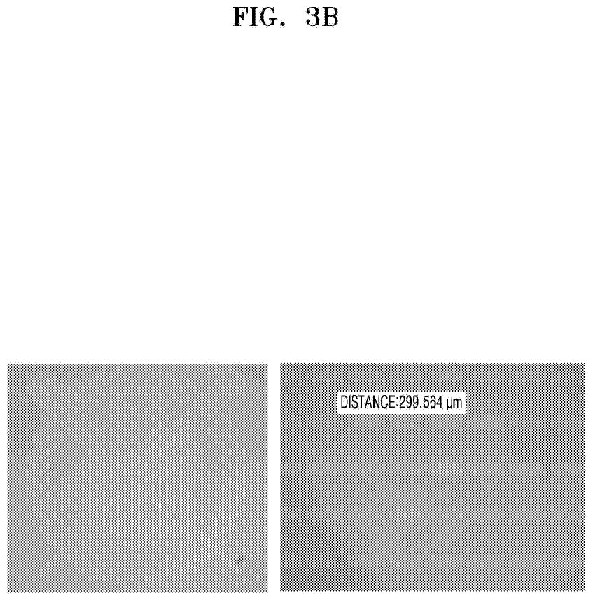

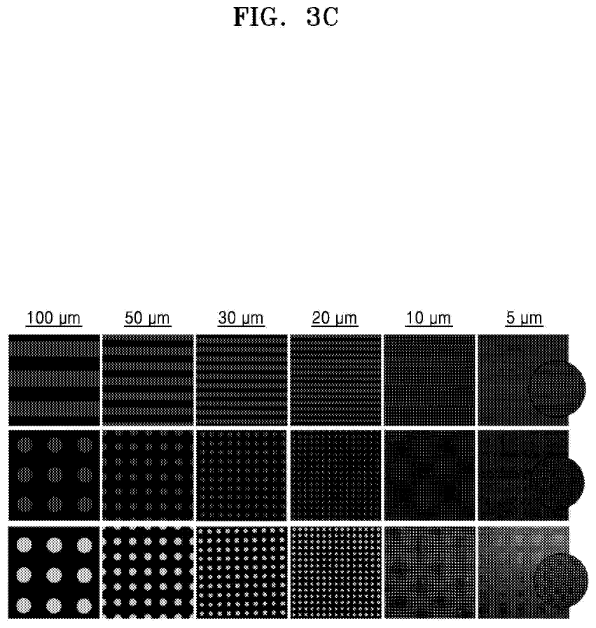

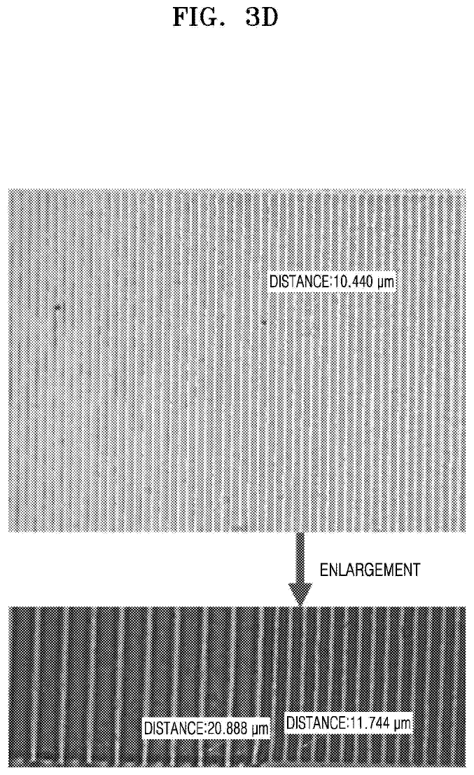

FIG. 3 shows images of a patterned emissive layer according to an embodiment of the disclosure. The emissive layer may be a crosslinked thin film formed by applying an emissive layer-forming solution including perovskite nanocrystals and a crosslinking compound, and then irradiating light, or a patterned thin film formed through photopatterning.

The crosslinking compound may be positioned around an organic ligand of the perovskite nanocrystals, and a diazirine functional group may be photoactivated to perform a crosslinking reaction between the organic ligands. At the same time, since the stability of the perovskite nanocrystals is enhanced due to a high electron density at the terminal of the crosslinking compound, patterning may be performed without affecting an inner core of the perovskite nanocrystals and without degradation of light-emitting properties. In addition, due to the improved stability of the perovskite nanocrystals caused by the crosslinking compound, a perovskite film may be formed to have a thickness of about 10 nm to about 3 μm, and a precise and uniform pattern may be formed up to a thickness of 1 μm.

FIG. 3A is a confocal image showing a patterned film having a thickness of 30 nm according to an embodiment of the disclosure, wherein the confocal image is captured by using an FV 4000 product manufactured by Olympus). It may be confirmed that precise patterning has been achieved. FIG. 3B is an optical microscope (OM) image showing a patterned film used for imaging in FIG. 3A, wherein the OM image is captured by using a BX53MTRF-S product manufactured by Olympus). It may be confirmed that precise patterning has been achieved. FIG. 3C shows images showing a patterned film according to scales when various patterns are applied to a film having a thickness of 30 nm. It may be confirmed that precise patterning has been achieved.

FIG. 3D shows images of a 2 μm-thick film patterned at 20 μm intervals and 10 μm intervals according to an embodiment of the disclosure, wherein an upper image is an image showing the film patterned at 10 μm intervals, and lower enlarged images are an enlarged OM image (left) showing the film patterned at 20 μm intervals and an enlarged OM image (right) showing the film patterned at 10 μm intervals. As can be seen from the images, it may be confirmed that uniform and precise patterning has been achieved even on a 2 um-thick film.

FIG. 3B shows a patterned film having a thickness of 2 μm according to an embodiment of the disclosure, and FIG. 3C is an enlarged view of FIG. 3B. Referring to FIGS. 3A to 3C, it may be confirmed that consistent excellent patterning has been performed at all of thicknesses of 30 nm to 2 μm according to an embodiment of the disclosure.

Hereinafter, an embodiment of the disclosure will be described through examples and comparative examples, and the scope of the disclosure is not intended to be limited to the examples.

### Preparation Example 1—Preparation of Perovskite Compound (FAPbBr₃)

Precursors of 0.1 mmol of FABr and 0.2 mmol of GABr were dissolved in 0.5 mL of N,N-dimethylformamide. 0.15 mL of a precursor solution was injected into a solution in which 5 mL of toluene, 2 mL of butanol, 0.3 mL of an oleic acid, and 24 μL of n-decylamine were mixed. The solution was vigorously stirred for 10 minutes, and FAPbBr₃ was synthesized. After 10 minutes, the entire solution was transferred to a conical tube and centrifuged at a speed of 12,000 rpm for 10 minutes. A supernatant was discarded, precipitated particles were redispersed in 1 ml of toluene, and then second centrifugation was performed at a speed of 3,750 rpm to remove aggregated particles and use a supernatant. 6 mg/ml of a perovskite nanocrystal solution was prepared.

1.5 ml of ethyl acetate or methyl acetate was added to 1 ml of a prepared FAPbBr₃ solution, and centrifugation was performed at a speed of 12,000 rpm for 5 minutes to precipitate particles. The precipitated particles were redispersed in toluene in which a target ligand (n-decylamine or tributylphosphine oxide) at a concentration of 2 mM was dissolved, and centrifugation was performed at a speed of 3,750 rpm for 5 minutes to remove aggregates. A corresponding supernatant was filtered by using a 0.2 polytetrafluoroethylene (PTFE) filter.

### Preparation Example 2—Synthesis of Compound 1

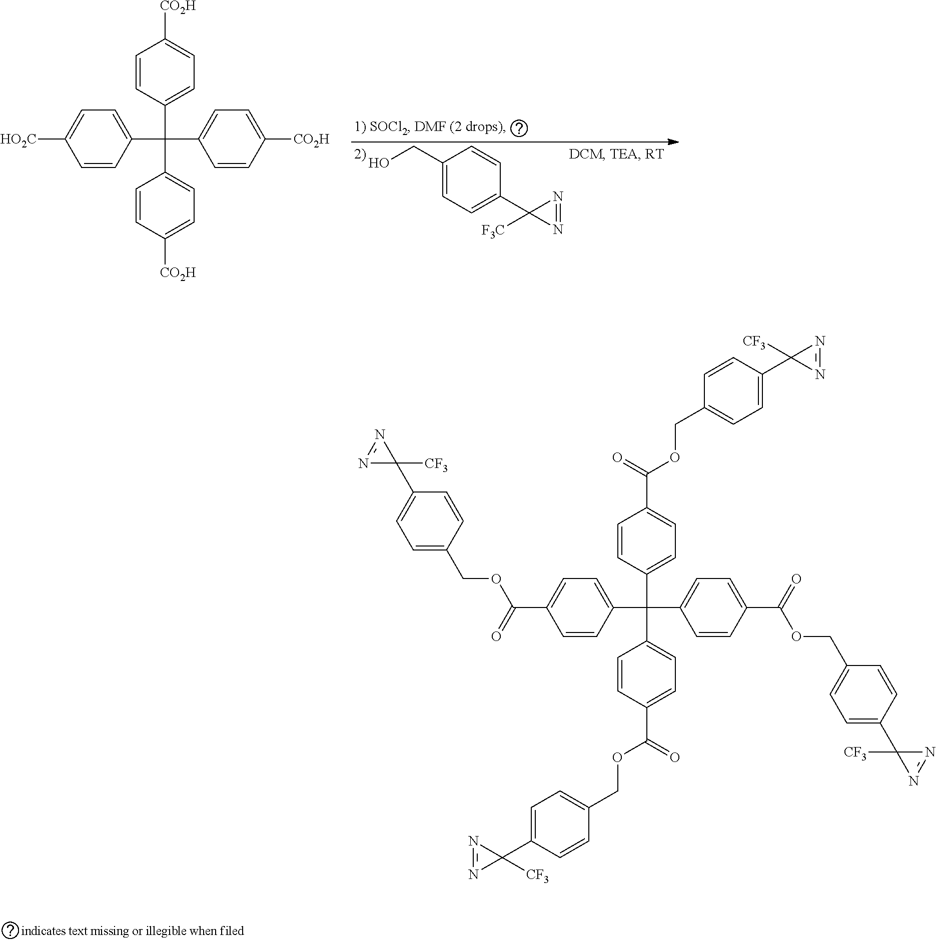 [SMILES: O=C(O)c1ccc(C(c2ccc(C(=O)O)cc2)(c2ccc(C(=O)O)cc2)c2ccc(C(=O)O)cc2)cc1 ; OCc1ccc(C2(C(F)(F)F)N=N2)cc1 ; O=C(OCc1ccc(C2(C(F)(F)F)N=N2)cc1)c1ccc(C(c2ccc(C(=O)OCc3ccc(C4(C(F)(F)F)N=N4)cc3)cc2)(c2ccc(C(=O)OCc3ccc(C4(C(F)(F)F)N=N4)cc3)cc2)c2ccc(C(=O)OCc3ccc(C4(C(F)(F)F)N=N4)cc3)cc2)cc1]

A dried magnetic bar was prepared and put into a 10 mL round-bottom flask. The round-bottom flask was vacuum-dried while being heated with a torch, and then filled with argon. A 4,4′,4″,4′″-methanetetrayltetrabenzoic acid (600 mg, 1.2058 mmol) was added to the flask and vacuum-dried for 1 hour. A mixture was prepared by sequentially adding thionyl chloride (SOCl₂) (0.1 mL, 1.4502 mmol) and anhydrous dimethylformamide (DMF) (2 drops) to the flask. The mixture was heated to 65° C. and stirred for 23 hours. The mixture was cooled to room temperature, an organic solvent was removed by using a rotary evaporator, and then the mixture was additionally dried by using a vacuum pump to obtain a product. The product was diluted with anhydrous dichloromethane (DCM) (5 mL) to prepare a first mixture, which was prepared under an argon atmosphere.

A magnetic bar was prepared and put into a separate 25 mL round-bottom flask. The round-bottom flask was vacuum-dried while being heated with a torch, and then filled with argon. (4-(3-(trifluoromethyl)-3H-diazirin-3-yl)phenyl)methanol (600 mg, 5.3175 mmol), anhydrous triethylamine (TEA) (1.4 mL, 9.7287 mmol), and DCM (10 mL) were added to the flask and stirred to prepare a mixture. The previously prepared first mixture was added dropwise to the mixture to prepare a second mixture. The second mixture was stirred at room temperature for 8 hours, and then distilled water (10 mL) was added to terminate the reaction. An extraction process was performed on the second mixture by using a separatory funnel, distilled water, and DCM (30 mL). An organic layer obtained by repeating the extraction process three times was dehydrated by using anhydrous MgSO₄, and then an organic solvent was removed by using a rotary evaporator. As a result, an obtained organic material was separated by silica gel column chromatography (ethylacetate:n-hexane=1:5) to obtain a white solid product. The solid product was analyzed and had a weight of 913.5 mg and a yield of 59%.

### Preparation Example 3—Synthesis of Compound 2

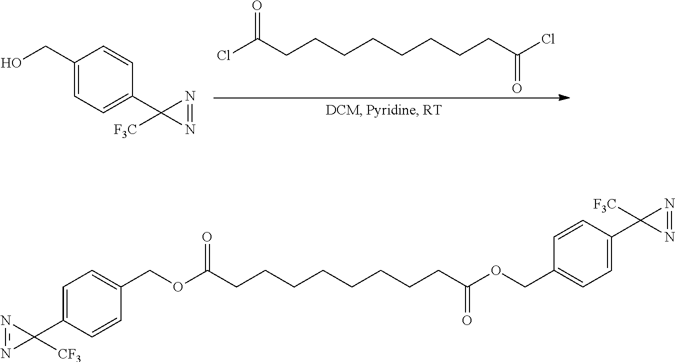 [SMILES: OCc1ccc(C2(C(F)(F)F)N=N2)cc1 ; O=C(Cl)CCCCCCCCC(=O)Cl ; O=C(CCCCCCCCC(=O)OCc1ccc(C2(C(F)(F)F)N=N2)cc1)OCc1ccc(C2(C(F)(F)F)N=N2)cc1]

A dried magnetic bar was prepared and put into a 25 mL round-bottom flask. The round-bottom flask was vacuum-dried while being heated with a torch, and then filled with argon. (4-(3-(trifluoromethyl)-3H-diazirine-3-yl)phenyl)methanol) (707.6 mg, 3.2735 mmol), anhydrous DCM (11.7 mL), and anhydrous pyridine (0.3 mL, 3.5073 mmol) were sequentially added to the flask and stirred to prepare a mixture. Sebacoyl chloride (279.7 mg, 1.1691 mmol) was added dropwise to the mixture to prepare a mixture. The mixture was stirred at room temperature for 8 hours, and then distilled water (10 mL) was added to terminate the reaction. An extraction process was performed on the mixture by using a separatory funnel, distilled water, and DCM (30 mL). An organic layer obtained by repeating the extraction process three times was dehydrated by using anhydrous MgSO₄, and then an organic solvent was removed by using a rotary evaporator. As a result, an obtained organic material was separated by silica gel column chromatography (ethylacetate:n-hexane=1:8) to obtain a white solid product. The solid product was analyzed and had a weight of 400 mg and a yield of 57%.

### Preparation Example 4—Synthesis of Compound 3

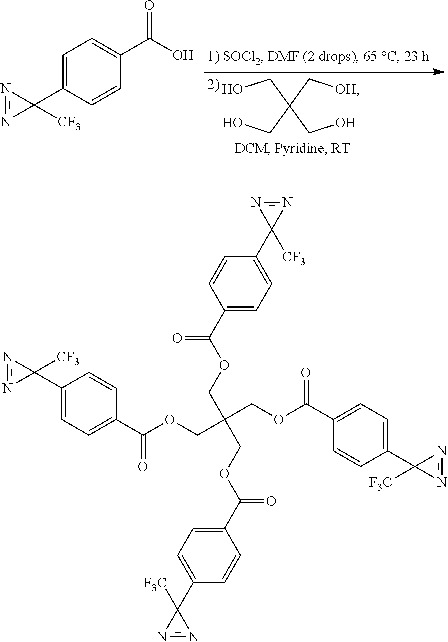 [SMILES: O=C(O)c1ccc(C2(C(F)(F)F)N=N2)cc1 ; OCC(CO)(CO)CO ; O=C(OCC(COC(=O)c1ccc(C2(C(F)(F)F)N=N2)cc1)(COC(=O)c1ccc(C2(C(F)(F)F)N=N2)cc1)COC(=O)c1ccc(C2(C(F)(F)F)N=N2)cc1)c1ccc(C2(C(F)(F)F)N=N2)cc1]

A dried magnetic bar was prepared and put into a 10 mL round-bottom flask. The round-bottom flask was vacuum-dried while being heated with a torch, and then filled with argon. A 4-(3-(trifluoromethyl)-3H-diazirin-3-yl)benzoic acid (1,008 mg, 4.3798 mmol) was added to the flask and vacuum-dried for 1 hour. A mixture was prepared by sequentially adding thionyl chloride (SOCl₂) (0.4 mL, 5.2558 mmol) and anhydrous DMF (2 drops) to the flask. The mixture was heated to 65° C. and stirred for 23 hours. The mixture was cooled to room temperature, an organic solvent was removed by using a rotary evaporator, and then the mixture was additionally dried by using a vacuum pump to obtain a product. The product was diluted with anhydrous DCM (6 mL) to prepare a first mixture, which was prepared under an argon atmosphere.

A magnetic bar was prepared and put into a separate 25 mL round-bottom flask. The round-bottom flask was vacuum-dried while being heated with a torch, and then filled with argon. Pentaerythritol (114.7 mg, 0.8423 mmol) and anhydrous pyridine (11.5 mL) were added to the flask and stirred to prepare a mixture. The previously prepared first mixture was added dropwise to the mixture to prepare a second mixture. The second mixture was stirred at room temperature for 8 hours, and then distilled water (12 mL) was added to terminate the reaction. An extraction process was performed on the second mixture by using a separatory funnel, distilled water, and DCM (30 mL). An organic layer obtained by repeating the extraction process three times was dehydrated by using anhydrous MgSO₄, and then an organic solvent was removed by using a rotary evaporator. As a result, an obtained organic material was separated by silica gel column chromatography (ethylacetate:n-hexane=1:6) to obtain a white solid product. The solid product was analyzed and had a weight of 248.8 mg and a yield of 30%.

### Preparation Example 5—Synthesis of Compound 4

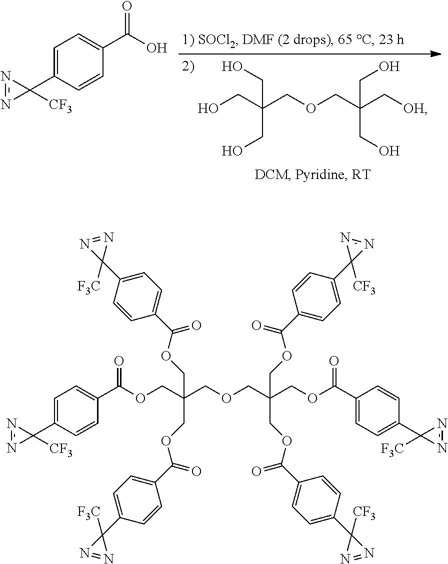 [SMILES: O=C(O)c1ccc(C2(C(F)(F)F)N=N2)cc1 ; OCC(CO)(CO)COCC(CO)(CO)CO ; O=C(OCC(COCC(COC(=O)c1ccc(C2(C(F)(F)F)N=N2)cc1)(COC(=O)c1ccc(C2(C(F)(F)F)N=N2)cc1)COC(=O)c1ccc(C2(C(F)(F)F)N=N2)cc1)(COC(=O)c1ccc(C2(C(F)(F)F)N=N2)cc1)COC(=O)c1ccc(C2(C(F)(F)F)N=N2)cc1)c1ccc(C2(C(F)(F)F)N=N2)cc1]

A dried magnetic bar was prepared and put into a 10 mL round-bottom flask. The round-bottom flask was vacuum-dried while being heated with a torch, and then filled with argon. A 4-(3-(trifluoromethyl)-3H-diazirin-3-yl)benzoic acid (863.2 mg, 3.7507 mmol) was added to the flask and vacuum-dried for 1 hour. A mixture was prepared by sequentially adding thionyl chloride (SOCl₂) (0.3 mL, 4.5008 mmol) and anhydrous DMF (2 drops) to the flask. The mixture was heated to 65° C. and stirred for 23 hours. The mixture was cooled to room temperature, an organic solvent was removed by using a rotary evaporator, and then the mixture was additionally dried by using a vacuum pump to obtain a product. The product was diluted with anhydrous DCM (7 mL) to prepare a first mixture, which was prepared under an argon atmosphere.

A magnetic bar was prepared and put into a separate 25 mL round-bottom flask. The round-bottom flask was vacuum-dried while being heated with a torch, and then filled with argon. Dipentaerythritol (116.3 mg, 0.4574 mmol) and anhydrous pyridine (12.0 mL) were added to the flask and stirred to prepare a mixture. The previously prepared first mixture was added dropwise to the mixture to prepare a second mixture. The second mixture was stirred at room temperature for 8 hours, and then an organic solvent was removed at a temperature 40° C. by using a rotary evaporator. Accordingly, an obtained solid product was separated by silica gel column chromatography (ethylacetate:DCM:n-hexane=1:2:8) to obtain a white solid product. The solid product was analyzed and had a weight of 168.2 mg and a yield of 24%.

### Example 1—Preparation of Perovskite Solution

Precipitated nanocrystals were redispersed in toluene in which 10 wt % of a crosslinking compound prepared in Preparation Example 1 (10 wt % based on particles, 0.6 mg/ml in the this case) was dissolved together with a target ligand (n-decylamine or tributylphosphine oxide) in the perovskite solution, and centrifuged at a speed of 3,750 rpm for 5 minutes to remove aggregates. A corresponding supernatant was filtered by using a 0.2 PTFE filter.

### Examples 2 and 3

Perovskite patterning solutions were prepared in the same manner as in Example 1, except that contents of crosslinking compounds were changed to 20 wt % (Example 2) and 30 wt % (Example 3), respectively.

### Comparative Example 1—Preparation of Perovskite Solution

A perovskite patterning solution was prepared in the same manner as in Example 1, except that a crosslinker solution was not separately prepared, and nanocrystals were dispersed directly in 1 mL of toluene.

### Comparative Example 2—Preparation of Perovskite Solution

A perovskite patterning solution was prepared in the same manner as in Example 1, except that, during preparation of a crosslinker solution, an azide compound (Azide-4Bx, 10 wt %, 0.6 mg/ml in this case) having the following structure was used instead of a diazirine compound.

### (Azide-4Bx)

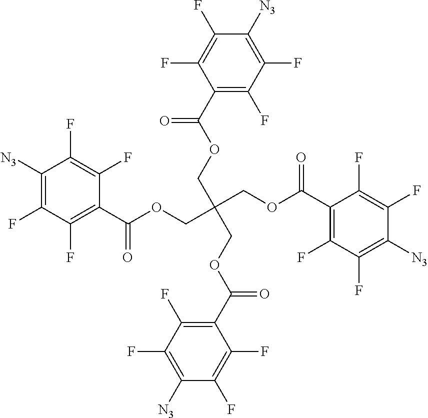 [SMILES: [N-]=[N+]=Nc1c(F)c(F)c(C(=O)OCC(COC(=O)c2c(F)c(F)c(N=[N+]=[N-])c(F)c2F)(COC(=O)c2c(F)c(F)c(N=[N+]=[N-])c(F)c2F)COC(=O)c2c(F)c(F)c(N=[N+]=[N-])c(F)c2F)c(F)c1F]

### Evaluation Example 1—PLQY Evaluation According to Content of Crosslinking Compound

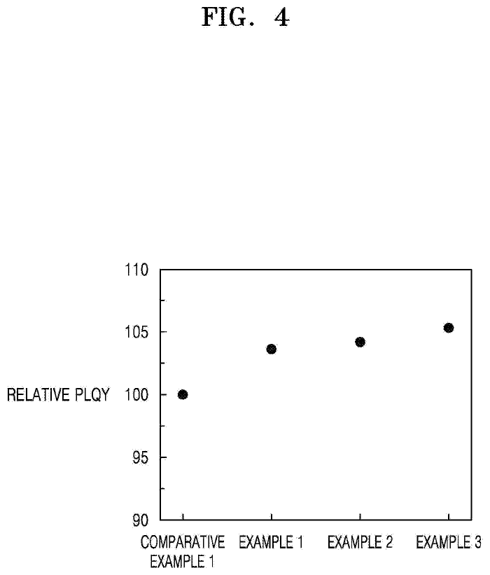

For the perovskite solutions prepared in Comparative Example 1 and Examples 1 to 3, 200 μL of a solution was put into a cuvette, and photoluminescence (PL) spectra were measured by using a JASCO FP8500 spectrofluorometer. Photoluminescence quantum yield (PLQY) was measured by using a 100 nm integrating sphere (ILF-835) mounted on the JASCO FP8500 spectrofluorometer and calculated through JASCO SpectraManager II software. Results thereof are shown in FIG. 4.

Referring to FIG. 4, it was confirmed that the PL efficiency of perovskite nanocrystals tended to increase as a content of a crosslinking compound increased. Such a result suggests that, due to an increased electron density of a terminal group, a crosslinking compound causes an effect of stabilizing perovskite nanocrystals without degrading the physical properties of the perovskite nanocrystals.

### Example 4—Preparation of Film

A glass substrate was spin-coated with the perovskite solution prepared in Example 1 at a speed of 500 rpm to prepare a film.

### Examples 5 and 6 and Comparative Example 3

Films were prepared in the same manner as in Example 4, except that the perovskite solutions prepared in Example 2, Example 3, and Comparative Example 1 were used, respectively.

### Evaluation Example 2—Evaluation of PLQY of Film

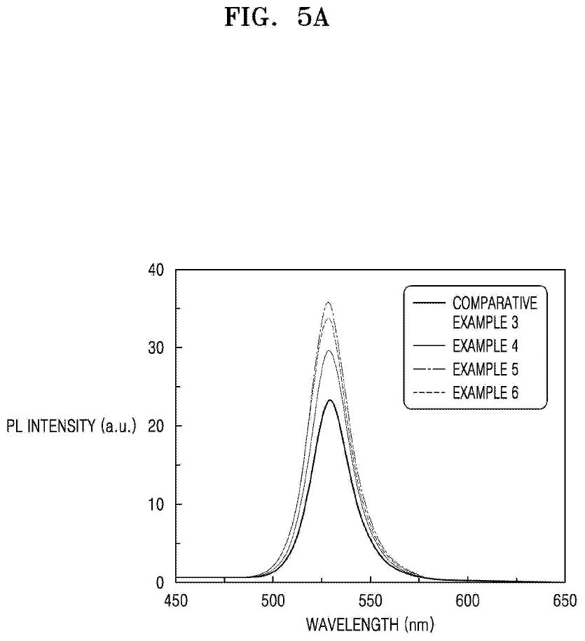

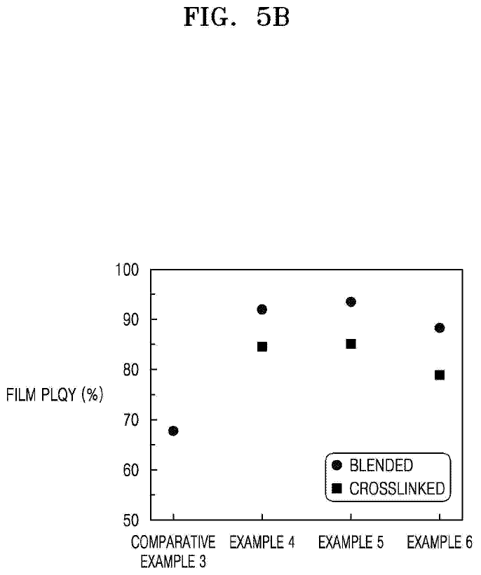

The PL spectra of the films prepared in Examples 4 to 6 and Comparative Example 3 were measured by using a JASCO FP8500 spectrofluorometer. Results thereof are shown in FIG. 5A.

In addition, the films prepared in Examples 4 to 6 and Comparative Example 3 were exposed to a UV lamp for 10 minutes to measure photoluminescence quantum yield (PLQY) before and after crosslinking. Results thereof are shown in FIG. 5B.

Referring to FIGS. 5A and 5B, it was confirmed that physical properties of a perovskite film in which a crosslinking compound was mixed were not degraded due to the crosslinking compound, and in a film including a crosslinking compound, photoluminescence quantum yield was improved by about 15% or more as compared to a case in which a crosslinking compound was not applied.

### Evaluation Example 3—Evaluation of PL Lifetime

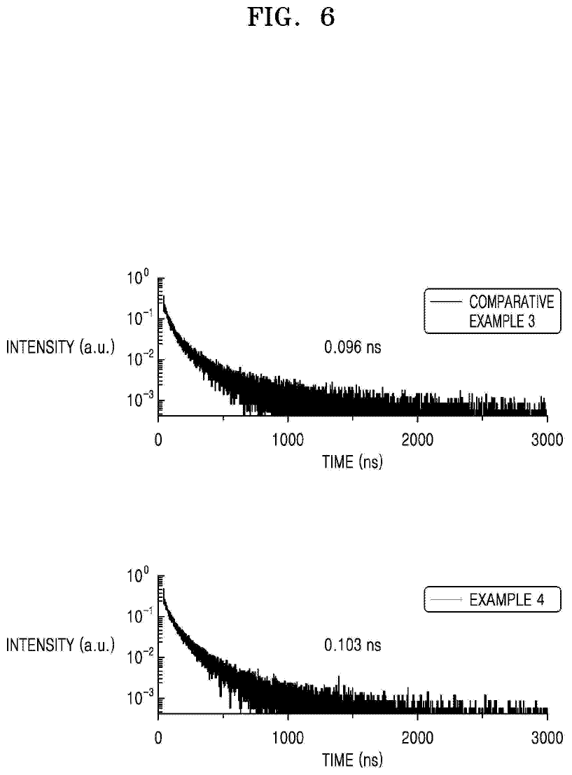

A crosslinked film obtained by crosslinking the film prepared in Example 4 through UV irradiation and the film prepared in Comparative Example 3 were measured by using a FluoTime 300 system under the following measurement conditions. Results thereof are shown in FIG. 6.

Measurement conditions: A 405 nm wavelength laser was used as an excitation source by using a picosecond-563 pulse laser head (LDH-PC-405B manufactured by PicoQuant), and detection was performed by using a photon-counting detector (PMA Hybrid 07) and a time-565 correlated single photon counting (TCSPC) module (PicoHarp manufactured by PicoQuant).

Referring to FIG. 6, it was confirmed that a PL lifetime was increased in the crosslinked film of Example 4. Such a result suggests that a crosslinking compound contributes to the stabilization of perovskite nanocrystals.

### Evaluation Example 4—Lattice Stabilization of Perovskite Nanocrystals Against Light

For the crosslinked film obtained by crosslinking the film prepared in Example 4 through UV irradiation and the film prepared in Comparative Example 3, grazing-incidence wide-angle X-ray scattering (GIWAXS) was analyzed by using beamline 3C (wavelength of 1.305 Å) of Pohang Accelerator Laboratory (PAL) in a state in which light was not present, and blue light was turned on.

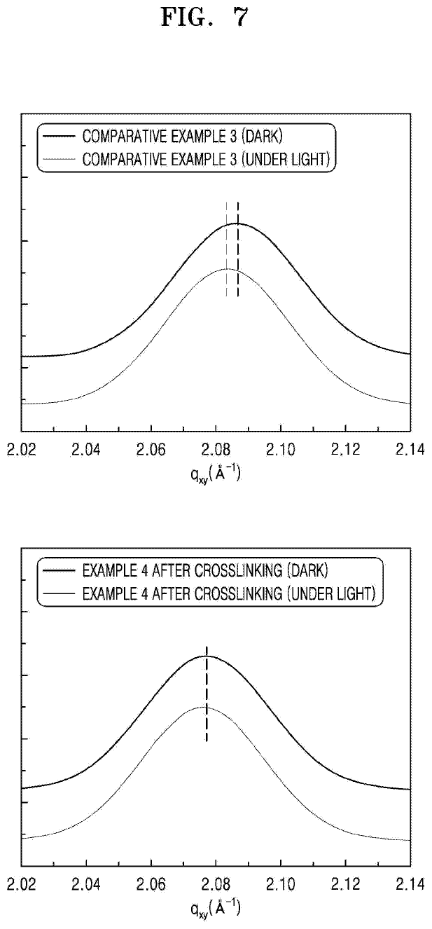

Analysis results are shown in FIG. 7. Referring to FIG. 7, it was confirmed that a perovskite lattice was stabilized against light due to the addition of a crosslinking compound. It was confirmed that a change in lattice distance due to light was reduced by crosslinking, thereby confirming that lattice expansion due to light could be suppressed through crosslinking.

### Evaluation Example 5—Lattice Stabilization of Perovskite Nanocrystals Against Heat

For the crosslinked film obtained by crosslinking the film prepared in Example 4 through UV irradiation and the film prepared in Comparative Example 3, GIWAXS was measured using by beamline 3C (wavelength of 1.305 Å) of PAL, and a coefficient of thermal expansion was calculated by using a (200) plane q value according to temperature.

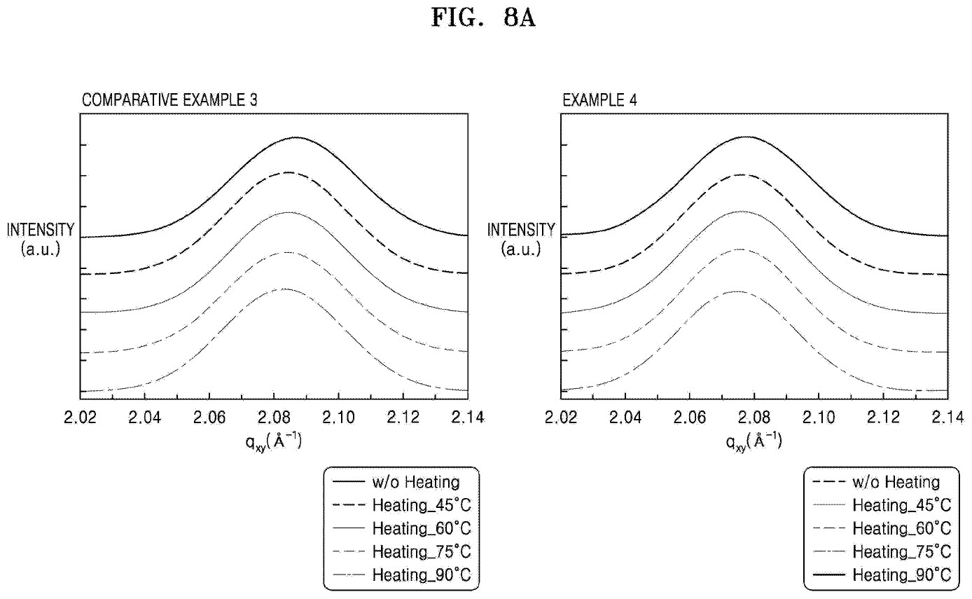

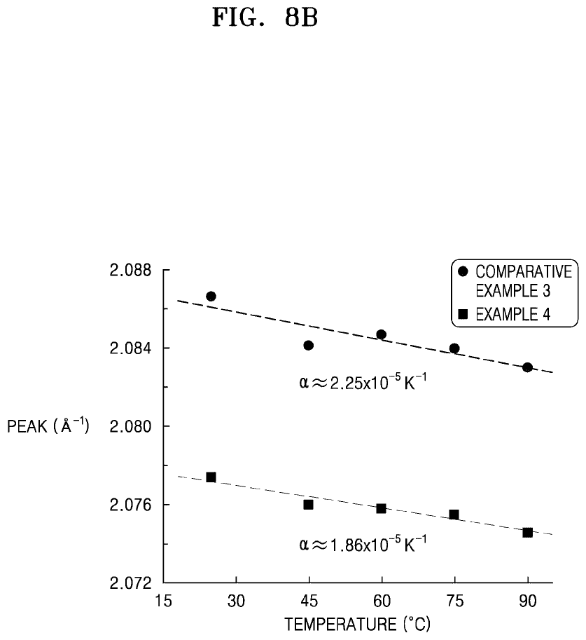

Analysis results are shown in FIGS. 8A and 8B. Referring to FIGS. 8A and 8B, it was confirmed that a coefficient of thermal expansion of crosslinked perovskite nanocrystals in Example 4 was smaller than that of perovskite nanocrystals in Comparative Example 3 due to the addition of a crosslinking compound, thereby indicating that lattice expansion due to heat was suppressed.

### Evaluation Example 6—Surface of Film

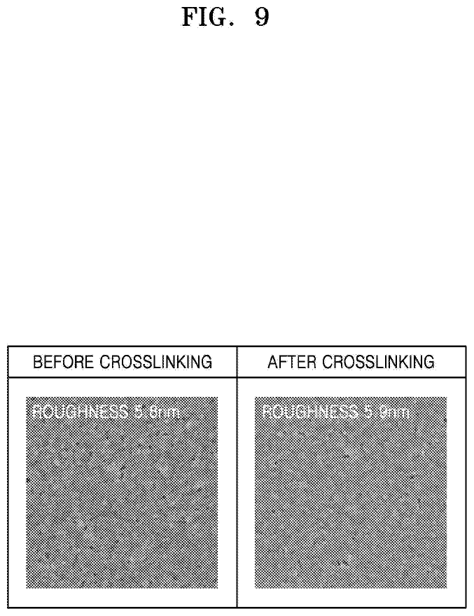

Scanning electron microscope (SEM) images of a surface of the film prepared in Example 4 before and after crosslinking through UV irradiation are shown in FIG. 9. Referring to FIG. 9, it may be confirmed that a surface of a perovskite film may be maintained very uniform even after crosslinking.

### Evaluation Example 7—Evaluation of Hydrophobicity of Film

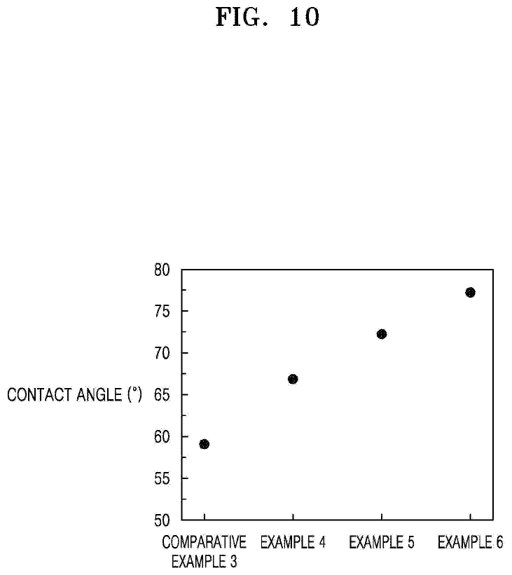

Drops of water were dropped on a surface of each of crosslinked films obtained by crosslinking the films prepared in Examples 4 to 6 through UV irradiation and the film prepared in Comparative Example 3, and a contact angle was measured. Results thereof are shown in FIG. 10.

Referring to FIG. 10, it was confirmed that the hydrophobicity of a film tended to increase as a content of a crosslinker increased, which indicated that it inhibited the penetration of moisture in the air into a perovskite film, thereby suppressing the decomposition of perovskite nanocrystals.

### Example 7—Manufacturing of Light-Emitting Device

ITO-patterned glass with a thickness of 70 nm was sequentially cleaned by ultrasonication in acetone and 2-isopropanol for 15 minutes each. After residual solvents were evaporated, the glass was treated with ozone for 10 minutes.

The ITO-patterned glass was spin-coated with a PEDOT:PSS solution to a thickness of 50 nm, and heat-treated at a temperature of 150° C. for 30 minutes to form a hole injection layer. Then, the hole injection layer was spin-coated with PVK to a thickness of 10 nm, and heat-treated at a temperature of 130° C. for 30 minutes to form a hole transport layer.

Next, 150 μL of a perovskite patterning solution prepared in Example 1 is placed on a substrate, dried for 4 minutes, and then spin coating was performed at a speed of 2,000 rpm for 30 seconds to form a perovskite emissive layer. The formed emissive layer was irradiated with UV light with a UV lamp for 10 minutes to prepare a crosslinked emissive layer. A photo mask was placed on the emissive layer, and then UV light was irradiated with a UV lamp for 10 minutes to form a patterned emissive layer. Afterwards, a nonpolar solvent was applied onto a surface of the emissive layer to remove a uncrosslinked portion.

Next, a 45 nm-thick electron transport layer including 2,2′,2″-(1,3,5-benzenetriyl)-tris(1-phenyl-1H-benzimidazole) (TPBi) was formed on the patterned emissive layer, and a 1 nm-thick LiF layer and an 80 nm-thick Al layer were sequentially formed to manufacture a perovskite light-emitting device.

Finally, the manufactured perovskite light-emitting device was encapsulated in an N₂ atmosphere by using a glass cover and a UV-curable epoxy resin.

### Comparative Example 4

A perovskite light-emitting device was manufactured in the same manner as in Example 7, except that the perovskite patterning solution prepared in Comparative Example 1 was used instead of the perovskite patterning solution prepared in Example 1, and a process of irradiating an emissive layer with UV light for 10 minutes using a UV lamp was omitted.

### Comparative Example 5

A perovskite light-emitting device was manufactured in the same manner as in Example 7, except that the perovskite patterning solution prepared in Comparative Example 2 was used instead of the perovskite patterning solution prepared in Example 1.

### Evaluation Example 8—Evaluation of Device Efficiency and Luminance

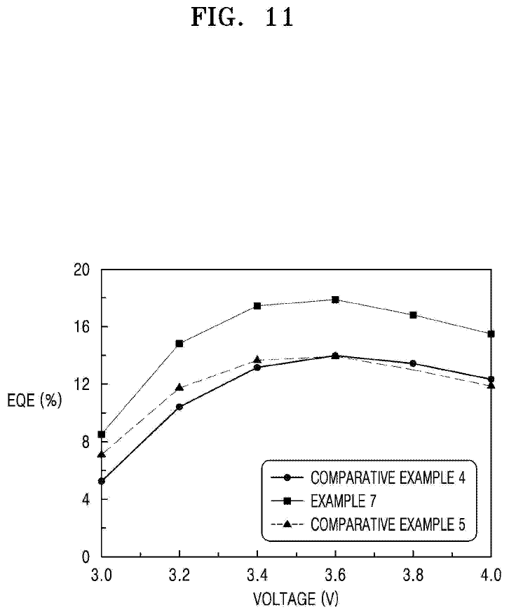

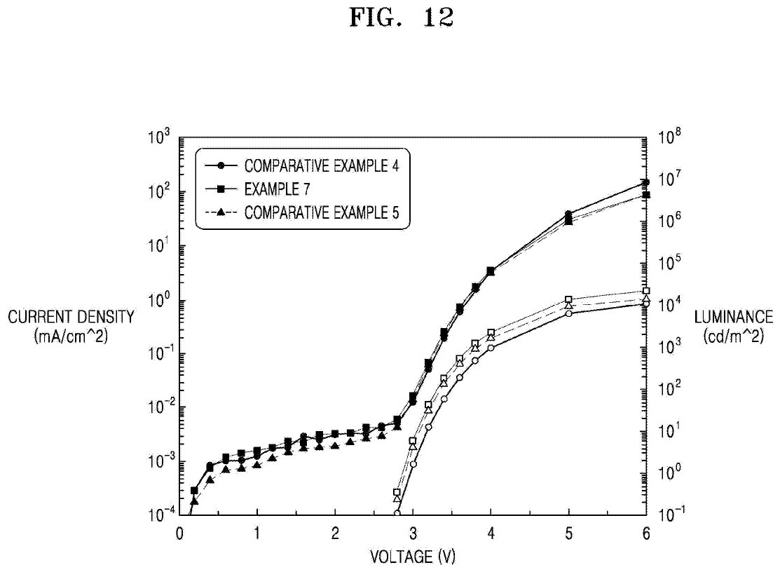

The efficiency and luminance of the perovskite light-emitting devices of Example 7 and Comparative Examples 4 and 5 were evaluated according to the following method. Results thereof are shown in FIGS. 11 and 12, respectively.

### <Measurement of Current Density-Voltage-Luminance (J-V-L)>

The current density-voltage-luminance of a light-emitting device was measured by using a Keithley 236 source measure unit and a Minolta CS 2000 spectroradiometer. Meanwhile, voltage-current efficiency was also measured.

### <Measurement of External Quantum Efficiency (EQE)>

The EQE of the light-emitting device was measured by using a Keithley 236 source measure unit and a Minolta CS 2000 spectroradiometer.

### <Measurement of Electroluminescence Spectra>

By using a Keithley 236 source measure unit and a Minolta CS 2000 spectroradiometer, the electroluminescence spectra of the light-emitting device was measured, and emission peaks were analyzed.

Referring to FIGS. 11 and 12, it was confirmed that the perovskite light-emitting device of Example 7 exhibited an efficiency improvement of 3% to 6% and an improvement in luminance as compared to the perovskite light-emitting device of Comparative Example 4. This means that an emissive layer of the perovskite light-emitting device of Example 7 was uniformly crosslinked, and perovskite nanocrystals were not deteriorated during a crosslinking process.

### Evaluation Example 9—Evaluation of Device Lifetime

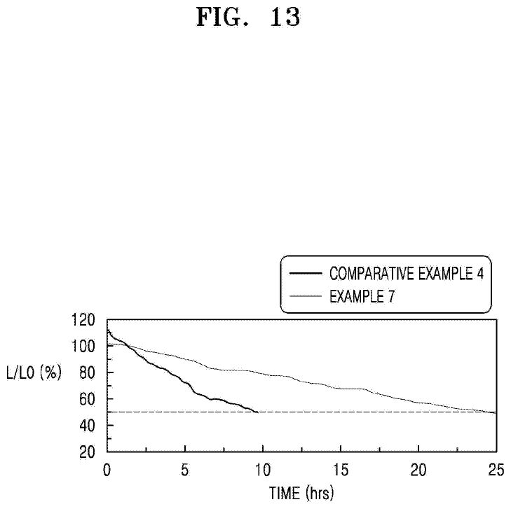

The lifetimes of the perovskite light-emitting devices of Example 7 and Comparative Examples 4 and 5 were evaluated according to the following method. Results thereof are shown in FIG. 13.

### <Method of Evaluating Operating Lifetime of Light-Emitting Device>

By using a Keithley 236 source measure unit and a Minolta CS 2000 spectroradiometer, the operating lifetime of the perovskite light-emitting device was determined by measuring luminance and electroluminescence spectra over time under an electrical stress condition of L₀=100 cd/m².

Referring to FIG. 13, it was confirmed that the half-like lifetime of the perovskite light-emitting device of Example 7 increased by about 300% as compared to the perovskite light-emitting device of Comparative Example 4. This is because, within an emissive layer, a crosslinking compound having a diazirine functional group intervenes between perovskite nanocrystals and crosslinks the perovskite nanocrystals, thereby stabilizing the perovskite nanocrystals and preventing ion migration.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

1. A film comprising perovskite nanocrystals and a crosslinking compound represented by Formula 1 or 2 below: 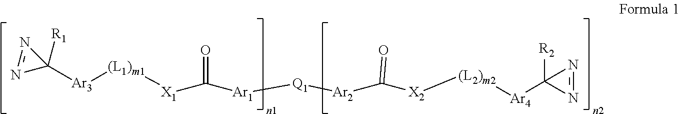
wherein, in Formula 1,
L₁ and L₂ are each independently selected from a single bond and a C₁-C₃₀ alkylene group, each unsubstituted or substituted with at least one R₁₀,
m1 and m2 are each independently 0, 1, 2, 3, 4, 5, or 6,
Ar₁ to Ar₄ are each independently selected from a single bond, a C₅-C₆₀ carbocyclic group, and a C₁-C₆₀ heterocyclic group, each unsubstituted or substituted with at least one R₁₀,
n1 and n2 are each independently 0, 1, 2, 3, 4, 5, 6, 7, 8, 9, or 10,
the sum of n1 and n2 is greater than or equal to 2,
Q₁ is selected from a single bond, O, S, Si, C, C(R₃), C(R₃)(R₄), N, N(R₃)(R₄), P, P(R₃)(R₄)(R₅), P═O(R₃), P═O(R₃) (R₄), SO₂, SO₂(R₃), and a C₁-C₃₀ alkylene group, each unsubstituted or substituted with at least one R₁₀,
X₁ is O,
X₂ is O, S, Se, N(R₆), or C(R₆)(R₇),
R₁ to R₇ and R₁₀ are each independently selected from hydrogen, deuterium, —CF₃, —CCl₃—F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group, and 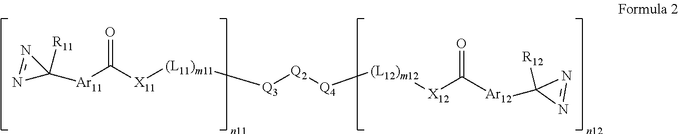
wherein, in Formula 2,
L₁₁ and L₁₂ are each independently selected from a single bond and a C₁-C₃₀ alkylene group, each unsubstituted or substituted with at least one R₁₀,
m11 and m12 are each independently 1, 2, 3, 4, 5, or 6,
Ar₁₁ and Ar₁₂ are each selected from a C₅-C₆₀ carbocyclic group, and a C₁-C₆₀ heterocyclic group, each unsubstituted or substituted with at least one R₁₀,
n11 and n12 are each independently 0, 1, 2, 3, 4, 5, 6, 7, 8, 9, or 10,
the sum of n11 and n12 is greater than or equal to 2,
Q₂ to Q₄ are each independently selected from a single bond, O, S, Si, C, C(R₁₃), C(R₁₃)(R₁₄), N, N(R₁₃), P, P(R₁₃)(R₁₄)(R₁₅), P═O(R₁₃), SO₂, a C₁-C₃₀ alkylene group, each unsubstituted or substituted with at least one R₁₀, and any combination thereof,
X₁₁ is O,
X₁₂ is selected from O, S, Se, N(R₁₆), and C(R₁₆)(R₁₇),
R₁₁ to R₁₇ and R₁₀ are each independently selected from hydrogen, deuterium, —CF₃, —CCl₃, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

2. The film of claim 1, wherein L₁ and L₂ are each independently selected from a methylene group, an ethylene group, a propylene group, and a butylene group, each unsubstituted or substituted with at least one R₁₀.

3. The film of claim 1, wherein, in Formula 1, X₂ is O or S.

4. The film of claim 1, wherein, in Formula 1, Ar₁ to Ar₄ are each independently selected from a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an aza-fluorene group, an aza-carbazole group, an aza-dibenzofuran group, an aza-dibenzothiophene group, an aza-dibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzoimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodisiline group, a dibenzodihydrosiline group, a dibenzodioxin group, a dibenzooxathine group, a dibenzooxazine group, a dibenzopyran group, a dibenzodithine group, a dibenzothiazine group, a dibenzothiopyran group, a dibenzocyclohexadiene group, a dibenzodihydropyridine group, and a dibenzodihydropyrazine group, each unsubstituted or substituted with at least one R₁₀.

5. The film of claim 1, wherein, in Formula 1, R₁ to R₇ and R₁₀ are each independently selected from: hydrogen, deuterium, —CF₃, —CCl₃, —F, —Cl, —Br, —I, a hydroxyl group, a cyano group, a C₁-C₂₀ alkyl group, a C₁-C₂₀ alkoxy group; a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, benzoimidazolyl group, a benzofuranyl group, a benzothienyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

6. The film of claim 1, wherein, in Formula 2, L₁₁ and L₁₂ are each independently selected from a methylene group, an ethylene group, a propylene group, and a butylene group, each unsubstituted or substituted with at least one R₁₀.

7. The film of claim 1, wherein, in Formula 2, X₁₂ is O or S.

8. The film of claim 1, wherein, in Formula 2, Ar₁₁ and Ar₁₂ are each independently selected from a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an aza-fluorene group, an aza-carbazole group, an aza-dibenzofuran group, an aza-dibenzothiophene group, an aza-dibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzoimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodisiline group, a dibenzodihydrosiline group, a dibenzodioxin group, a dibenzooxathine group, a dibenzooxazine group, a dibenzopyran group, a dibenzodithine group, a dibenzothiazine group, a dibenzothiopyran group, a dibenzocyclohexadiene group, a dibenzodihydropyridine group, and a dibenzodihydropyrazine group, each unsubstituted or substituted with at least one R₁₀.

9. The film of claim 1, wherein, in Formula 2, R₁₁ to R₁₇ and R₁₀ are each independently selected from: hydrogen, deuterium, —CF₃, —CCl₃, —F, —Cl, —Br, —I, a hydroxyl group, a cyano group, a C₁-C₂₀ alkyl group, a C₁-C₂₀ alkoxy group; a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thienyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, benzoimidazolyl group, a benzofuranyl group, a benzothienyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

10. The film of claim 1, wherein the crosslinking compound is selected from Compounds 1 to 7 below:

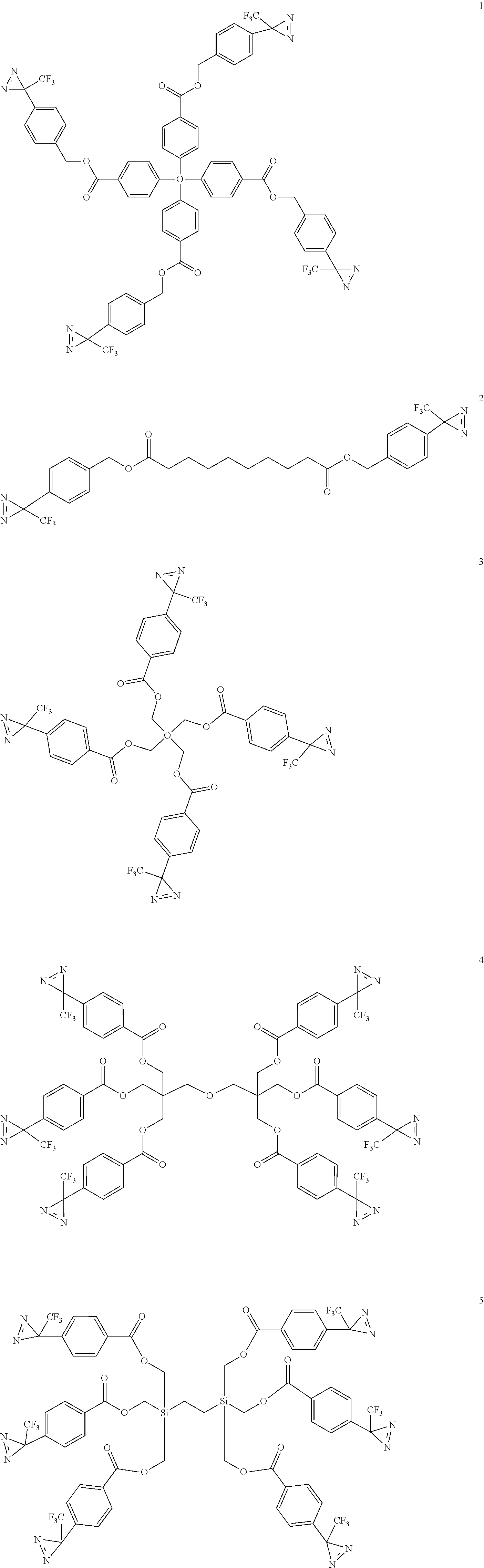

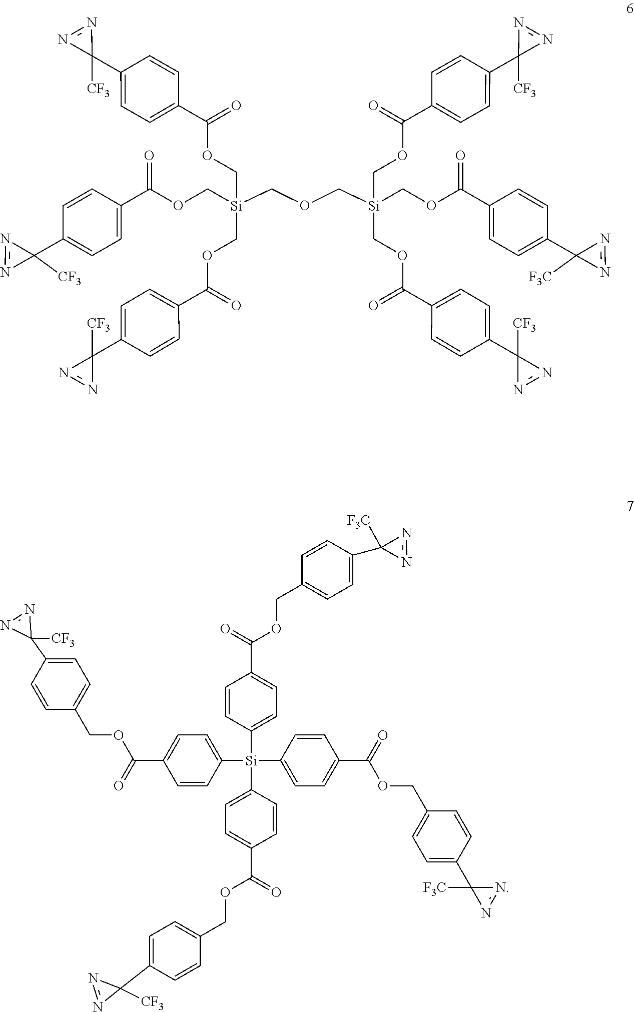 [SMILES: O=C(OC[Si](COC[Si](COC(=O)c1ccc(C2(C(F)(F)F)N=N2)cc1)(COC(=O)c1ccc(C2(C(F)(F)F)N=N2)cc1)COC(=O)c1ccc(C2(C(F)(F)F)N=N2)cc1)(COC(=O)c1ccc(C2(C(F)(F)F)N=N2)cc1)COC(=O)c1ccc(C2(C(F)(F)F)N=N2)cc1)c1ccc(C2(C(F)(F)F)N=N2)cc1 ; O=C(OCc1ccc(C2(C(F)(F)F)N=N2)cc1)c1ccc([Si](c2ccc(C(=O)OCc3ccc(C4(C(F)(F)F)N=N4)cc3)cc2)(c2ccc(C(=O)OCc3ccc(C4(C(F)(F)F)N=N4)cc3)cc2)c2ccc(C(=O)OCc3ccc(C4(C(F)(F)F)N=N4)cc3)cc2)cc1]

11. The film of claim 1, wherein the perovskite nanocrystals further comprise an organic ligand on at least a portion of a surface thereof.

12. The film of claim 1, wherein the perovskite nanocrystals comprise an ABX₃, A₄BX₆, AB₂X₅, A₂BX₄, A₂BX₆, A₂B⁺B³⁺X₆, A₃B₂X₉, or A′₂Aₖ₋₁BₖX₃ₖ₊₁ crystal structure,
wherein A and A′ are each independently selected from a monovalent organic cation, a monovalent inorganic cation, and a combination thereof,
B is selected from one or more metal ions,
X is selected from F⁻, Cl⁻, Br⁻, I⁻, SCN—, OCN—, SeCN—, HCO₂⁻, CH₃COO⁻, and a combination thereof, and
k is selected from an integer from 2 to 6.

13. The film of claim 12, wherein A and A′ each comprise an organic amidinium ion, an organic ammonium ion, Cs, Rb, or a combination thereof, and
B comprises a transition metal, a rare earth metal, an alkali metal, an alkaline earth metal, Pb, Sn, Ge, Ga, In, Al, Sb, Bi, Po, or a combination thereof.

14. The film of claim 13, wherein the organic amidinium ion comprises a formamidinium (NH₂CH═NH⁻) ion, an acetamidinium (NH₂C(CH)═NH₂⁺) ion, or a guanidinium (NHC(NH)═NH⁺) ion, and
the organic ammonium ion comprises a methylammonium ion, an ethylammonium ion, a tert-butylammonium ion, a diethylammonium ion, a dimethylammonium ion, an ethane-1,2-diammonium ion, an imidazolium ion, an n-propylammonium ion, an iso-propylammonium ion, a pyrrolidinium ion, CH(NH₂)₂⁺, CₓH₂ₓ₊₁(CNH₃)⁺, (CH₃NH₃)ₙ⁺, ((CₓH₂ₓ₊₁)ₙNH₃)ₙ(CH₃NH₃)ₙ⁺, R(NH₂)₂⁺ (R is a C₁-C₁₀₀ alkyl group), (CₙH₂ₙ₊₁NH₃)ₙ⁺, (CF₃NH₃)⁺, CF₃NH₃)ₙ⁺, ((CₓF₂ₓ₊₁)ₙNH₃)ₙ(CF₃NH₃)ₙ⁺, ((CₓF₂ₓ₊₁)ₙNH₃)₂⁺, or (CₙF₂ₙ₊₁NH₃)ₙ⁺ (n and x are each independently an integer from 1 to 100).

15. The film of claim 11, wherein the organic ligand comprises a carboxylic acid organic ligand, an amine organic ligand, a phosphonic acid organic ligand, a zwitterionic ligand, a multi-dentate ligand, or a combination thereof.

16. A perovskite light-emitting device comprising:
a first electrode;
a light-emitting layer positioned on the first electrode and comprising the film of any one of claims 1 to 15; and
a second electrode disposed on the light-emitting layer.

17. The perovskite light-emitting device of claim 16, wherein the light-emitting layer has a thickness of about 10 nm to about 100 nm.

18. The perovskite light-emitting device of claim 16, wherein the light-emitting layer is a patterned perovskite film.

19. A method of manufacturing a perovskite light-emitting device, the method comprising:
providing a first electrode;
forming, on the first electrode, a light-emitting layer comprising the film of any one of claims 1 to 15;
providing a second electrode on the light-emitting layer,
wherein the forming of the light-emitting layer comprises:
obtaining a first solution in which a crosslinking compound represented by Formula 1 or 2 below is dissolved in a nonpolar solvent;
adding perovskite nanocrystals to the first solution and stirring to obtain a second solution; and
applying the second solution onto the first electrode and patterning the applied second solution, 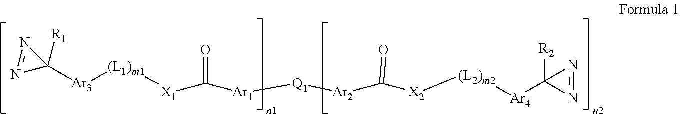
wherein, in Formula 1,
L₁ and L₂ are each independently selected from a single bond and a C₁-C₃₀ alkylene group, each unsubstituted or substituted with at least one R₁₀,
m1 and m2 are each independently 1, 2, 3, 4, 5, or 6,
Ar₁ to Ar₄ are each selected from a single bond, a C₅-C₆₀ carbocyclic group, and a C₁-C₆₀ heterocyclic group, each unsubstituted or substituted with at least one R₁₀,
n1 and n2 are each independently 0, 1, 2, 3, 4, 5, 6, 7, 8, 9, or 10,
the sum of n1 and n2 is greater than or equal to 2,
Q₁ is selected from a single bond, O, S, Si, C, C(R₃), C(R₃)(R₄), N, N(R₃)(R₄), P, P(R₃)(R₄)(R₅), P═O(R₃), P═O(R₃) (R₄), SO₂, SO₂(R₃), and a C₁-C₃₀ alkylene group, each unsubstituted or substituted with at least one R₁₀,
X₁ is O,
X₂ is O, S, Se, N(R₆), or C(R₆)(R₇),
R₁ to R₇ and R₁₀ are each independently selected from hydrogen, deuterium, —CF₃, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group, and 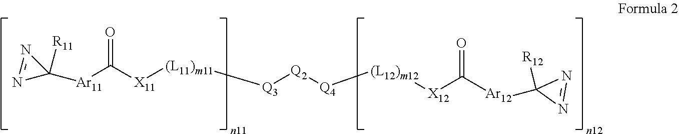
wherein, in Formula 2,
L₁₁ and L₁₂ are each independently selected from a single bond, and a C₁-C₃₀ alkylene group, each unsubstituted or substituted with at least one R₁₀,
m11 and m12 are each independently 1, 2, 3, 4, 5, or 6,
Ar₁₁ and Ar₁₂ are each selected from a C₅-C₆₀ carbocyclic group, and a C₁-C₆₀ heterocyclic group, each unsubstituted or substituted with at least one R₁₀,
n11 and n12 are each independently 0, 1, 2, 3, 4, 5, 6, 7, 8, 9, or 10,
the sum of n11 and n12 is greater than or equal to 2,
Q₂ to Q₄ are each independently selected from a single bond, O, S, Si, C, C(R₁₃), C(R₁₃)(R₁₄), N, N(R₁₃), P, P(R₁₃)(R₁₄)(R₁₅), P═O(R₁₃), SO₂, a C₁-C₃₀ alkylene group, and any combination thereof, each unsubstituted or substituted with at least one R₁₀,
X₁₁ is O,
X₁₂ is O, S, Se, N(R₁₆), or C(R₁₆)(R₁₇),
R₁₁ to R₁₇ and R₁₀ are each independently selected from hydrogen, deuterium, —CF₃, —CCl₃, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, a C₅-C₆₀ carbocyclic group, a C₁-C₆₀ heterocyclic group, and —Si(Q₁₁)(Q₁₂)(Q₁₃), and
Q₁₁ to Q₁₃ are each independently selected from hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, and a C₁-C₃₀ alkylthio group.

20. The method of claim 19, wherein the patterning comprises positioning a photomask on a coating film, then irradiating ultraviolet (UV) light, and then performing development with a nonpolar solvent.
